(19) United States
(12) Patent Application Publication
(10) Pub. No.: US 2016/0309574 A1
(43) Pub. Date: Oct. 20, 2016

(54) PRINTED CIRCUIT BOARD

(71) Applicant: CHUNG-PAO WANG, TAICHUNG (TW)

(72) Inventor: CHUNG-PAO WANG, TAICHUNG (TW)

(21) Appl. No.: 15/099,612

(22) Filed: Apr. 15, 2016

(30) Foreign Application Priority Data
Apr. 17, 2015 (TW) 104112330
Jan. 3, 2016 (TW) 105100003
Mar. 22, 2016 (TW) 105108796
Apr. 13, 2016 (TW) 105111470

(51) Int. Cl. H05K 1/02; H05K 1/11; H05K 3/00; H05K 1/18

(52) U.S. Cl. CPC H05K 1/0203; H05K 1/181; H05K 1/111; H05K 1/115; H05K 3/0035; H05K 3/0047; H05K 2201/0959

(57) ABSTRACT

A printed circuit board at least includes an insulator with a predetermined blind via area which may become a blind via which is penetrated through said insulator through a process of drilling. A portion of a conductive material may be filled therein to allow both the trace on the upper surface of the insulator and/or the conductive pad on the lower surface of insulator to be electrically connected. The quantity of the trace is increased. The blind via may also have a vent so that the gas sealed in the blind via enables to be released to the atmosphere promptly through the vent while heating.

### FIELD OF THE INVENTION

The present invention relates to a printed circuit board, and more particularly to a printed circuit board for bonding to electronic elements.

### BACKGROUND OF THE INVENTION

Please refer to FIGS. 15A to 15C, they show the structure and manufacturing steps of the conventional printed circuit board 5A. FIG. 15A shows the top view of the printed circuit board 5A, FIG. 15B shows the cross-sectional view of FIG. 15A along line C-C, and FIG. 15C shows the cross-sectional view of adding the first conductive material 95 after the printed circuit board 5A in FIG. 15B is finished. In FIGS. 15A and 15B, the printed circuit board 5A may comprises a first insulator 40, two first traces 70, a second trace 7A, a solder mask 80, and three protective layers 90. The first insulator 40 includes an upper surface 41, a lower surface 42, and a blind via 44 which is penetrated through said insulator 44. A lower surface 72 of each of the first trace 70 is bonded to the upper surface 41 of the first insulator 40. The lower surface 72 further includes a second lower surface 722. At least a portion of the second lower surface 722 is exposed to the blind via 44 of the first insulator 40. The second lower surface 722 may be employed as a conductive pad 3A which is provided for electrically connecting with other conductors such as solder ball, conductive paste, conductive layer or the like. The second trace 7A is arranged at the upper surface 41 of the first insulator 40 and located between the two first traces 70. The solder paste 80 is arranged at the upper surface 41 of the first insulator 40. A portion of the upper surface 71 of the first trace 70 is not covered by the solder mask 80 in order to be exposed to the atmosphere for external connection such as tin, nickel, conductive wire, conductive bump, conductive layer, solder ball, or other suitable conductors. Each of the protective layers 90 is bonded to the upper surface 71 and the second lower surface 722 of the first trace 70 which are exposed to the atmosphere. The protective layer 90 is generally composed of at least staking nickel and gold. For example, the four limitations of the printed circuit board 5A are described as followed. Firstly, the distance P between the two conductive pads 3A (the second lower surface 722 of the first trace 70) is 500 μm. Secondly, the width K of the conductive pad 3A is 250 μm. Thirdly, the width W of the second trace 7A is 50 μm. Fourthly, the distance (not numbered) between the second trace 7A and the first trace 70 is not smaller than 50 μm. Since the width K of the conductive pad 3A is 250 μm, the width D of the blind via 40 is 250 μm too. In order to prevent the first trace 70 from dropping into the blind via 44 of the first insulator 40 to result in damage. The width L of the first trace 70 which is arranged corresponding to the blind via 44 must add more 100 μm compared to the width D of the blind via 44 so that the smallest width L is 350 μm and the smallest distance S between the two first traces 70 is 150 μm. Therefore, only one second trace 7A may be arranged between the two first traces 70 so that the printed circuit board 5A is not good to the circuit with high density, therefore the application of said printed circuit board 5A is restricted, meanwhile, When the protective layer 90 is bonded to the first trace 70 by electroplating, the protective layer 90 must bonded to the second lower surface 722 of the first trace 70 so that the cost of the printed circuit board 5A is increased. In FIG. 15C, a process of filling the first conductive material 95 (such as solder paste) with solder balls in the blind via 44 is provided. The first conductive material 95 is viscous before filling into the blind via 44. The gas 97 may be sealed in the blind via 44 while filling the first conductive material 96 into the blind via 44. When the first conductive material 95 is heated before solidifying, the gas 97 will be expanding by heat. When the first conductive material 95 is forced out of the blind via 44 by the expending gas 97, parts of the conductive material 95f is forced out of the blind via 44 and dropped onto the lower surface 42 of the first insulator 40. If the conductive material 95f which is forced out is not removed, the conductive material 95f may be arranged between two solder balls 96 to electrically connect with the two solder balls 96 to result in the damage of short circuit while the two solder balls 96 are bonded to the printed circuit board 5A. Besides, when the width D of the blind via 44 is larger, the rigidity of the first insulator 40 is easy to become weaker. The first insulator 40 is easy to be bent and broken. When the quantity of the blind via 44 is more, it is easier to result in bending and damaging the first insulator 40. According to above descriptions, the printed circuit board 5A is not easy to increase the density of the circuit and reduce the cost. The first insulator 40 is easy to be bent and the short circuit may also be occurred easily.

In view of the foregoing circumstances, the inventor has invested a lot of time to study the relevant knowledge, compare the pros and cons, research and develop related products. After quite many experiments and tests, the “printed circuit board structure” of this invention is eventually launched to improve the foregoing shortcomings, to meet the public use.

### SUMMARY OF THE INVENTION

A printed circuit board structure and a process for the predetermined blind via area of the first insulator becoming a blind via are disclosed. Wherein the printed circuit board also comprises a conductive pad as demanded, When the printed circuit board comprises the conductive pad, the printed circuit board may be arranged at the lower surface of the insulator through the conductive pad so that the width of the trace arranged at the upper surface of the insulator may be shortened and the density of the circuit may be increased. An obstructer of first insulator received in the predetermined blind via area and coupled with the second lower surface of first trace so that the second lower surface of the trace is not exposed to the atmosphere and then the protective layer may be not arranged. Accordingly, the cost may be reduced. The peripheral of the predetermined blind via area may also include a predetermined vent area as demanded, so that the blind via which is penetrated through the first insulator may include a vent which is penetrated through the first insulator too. When the predetermined blind via area and the predetermined vent area become the real blind via and the real vent respectively, the blind via may include the real vent so that the gas sealed in the blind via may be exhausted outside through the vent while heating the conductive material after the conductive material is filled into the real blind via. Therefore, the quantity of a portion of the conductive material which is forced out of the blind via may be effectively reduced. And the damage of short circuit may be prevented. The printed circuit board may comprise a first insulator with the predetermined blind via area and a first trace arranged at the upper surface of the first insulator, and wherein a portion of said first trace arranged corresponding to the predetermined blind via area. Furthermore, in the process of fabricating a semiconductor package, a process of drilling is able to be provided either before or after the printed circuit is sealed by an encapsulant. When the predetermined blind via area becomes the blind via so that a portion of the lower surface of the first trace is exposed to the real blind via. A process of filling is provided after the printed circuit board includes the blind via and is sealed by an encapsulant. A conductive material is received in the blind via of the first insulator so as to electrically connect with the first trace and the first conductive pad through the conductive material and make the first trace electrically connect with the conductive pad. Besides, the peripheral of the blind via may also include one or more vents for effectively exhausting the gas or chemical solvent in the blind via and further preventing from damage of short circuit. In case that the first conductive pad is omitted, the peripheral of the blind via of the first insulator still enables to include the real vent(s). The drawback of short circuit may be also prevented. Meanwhile, since the first insulator includes the predetermined blind via area, the rigidity of the first insulator may be increased so as to prevent the first insulator from being bent and broken. In addition, when the ratio of the thickness of the first insulator and the width of the predetermined blind via area is a value in a suitable range, the damage of printed circuit board may be also prevented.

Further features and advantages of the present invention will become apparent to those of skill in the art in view of the detailed description of preferred embodiments which follows, when considered together with the attached drawings and claims.

### BRIEF DESCRIPTION OF THE DRAWINGS

All the objects, advantages, and novel features of the invention will become more apparent from the following detailed descriptions when taken in conjunction with the accompanying drawings.

FIGS. 1-1 to 1-3 are the top view and cross-sectional view of a predetermined blind via area or a blind via of a printed circuit board of the present invention.

FIGS. 2-1 to 2-3B are the cross-sectional view and bottom view of a predetermined vent area or a vent of the printed circuit board of the present invention.

FIG. 3 is a cross-sectional view of the printed circuit board of the present invention with elements (or a member).

FIGS. 4-1 to 5 are a cross-sectional view of the printed circuit board of the present invention without a conductive pad.

FIGS. 6A-1 to 6C-2 are the bottom view and cross-sectional view of the real vent and a gate of the printed circuit board of the present invention.

FIGS. 7A-1 to 7B-3 are the three-view diagrams of the printed circuit board of the present invention with shapes of real blind via.

FIGS. 8A-1 to 8B-2 are the top view and the cross-sectional view of the printed circuit board of the present invention with a second insulator.

FIGS. 9 to 10 are the cross-sectional views of the printed circuit board of the present invention with a second side edge.

FIGS. 11 to 14C are the cross-sectional views of drilling process for a predetermined blind via of first insulator being become a blind via of first insulator of the present invention.

FIGS. 15A to 15C are the top view and the cross-sectional view of a conventional printed circuit board.

### DESCRIPTION OF THE PREFERRED EMBODIMENT

Referring now to the drawings where like characteristics and features among the various figures are denoted by like reference characters.

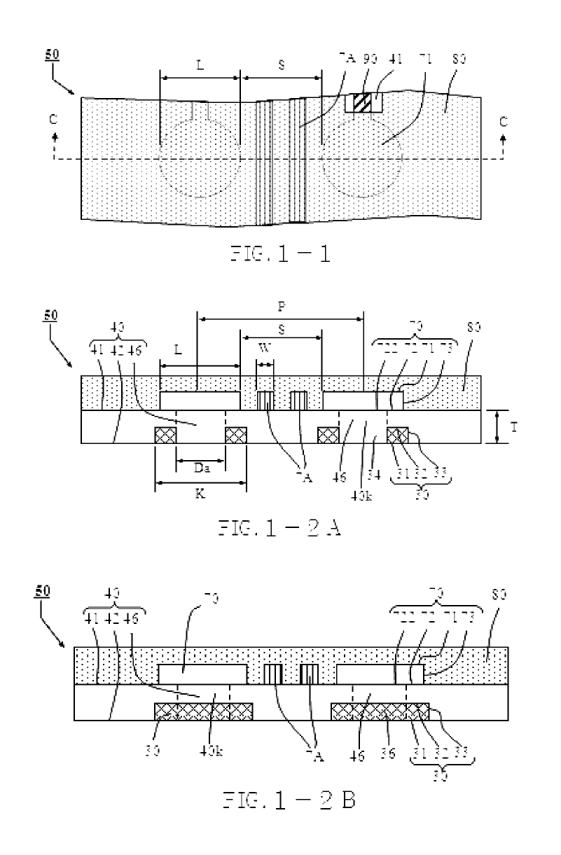

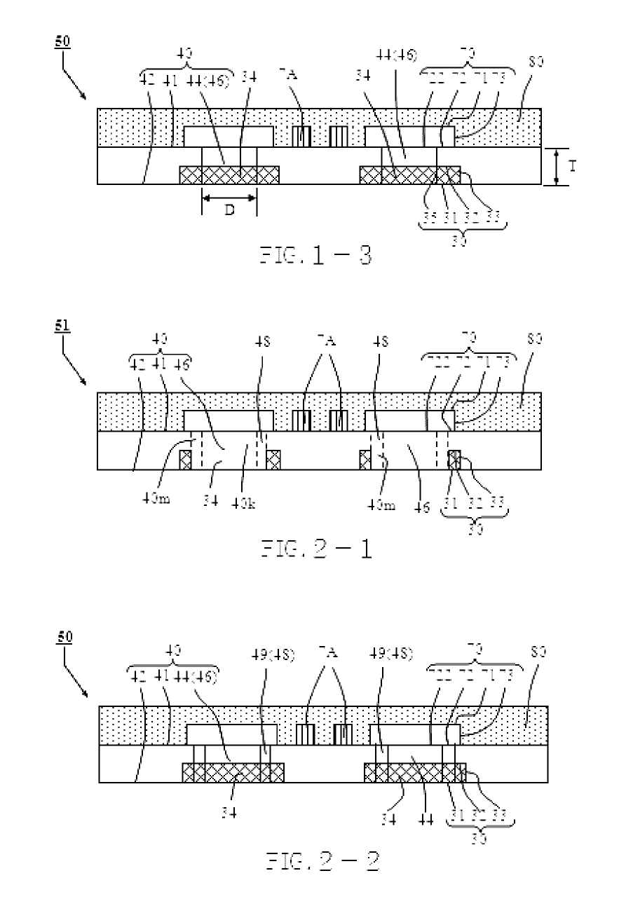

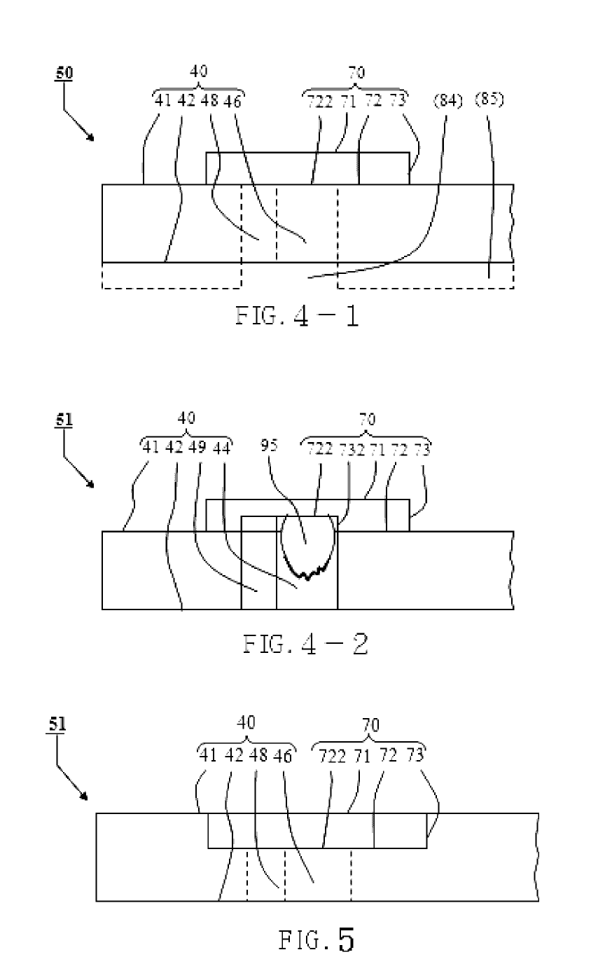

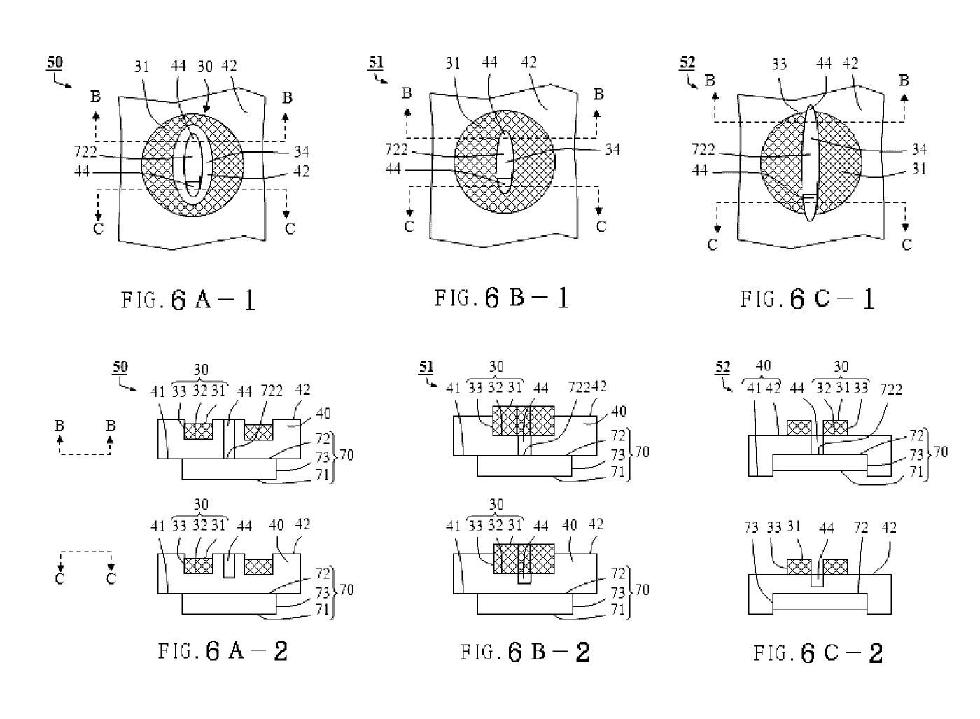

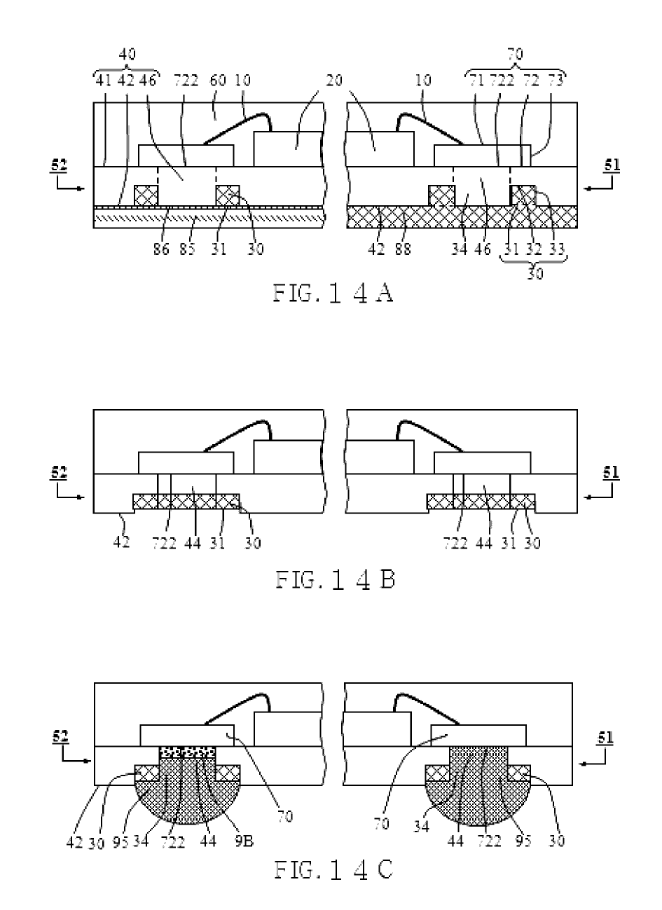

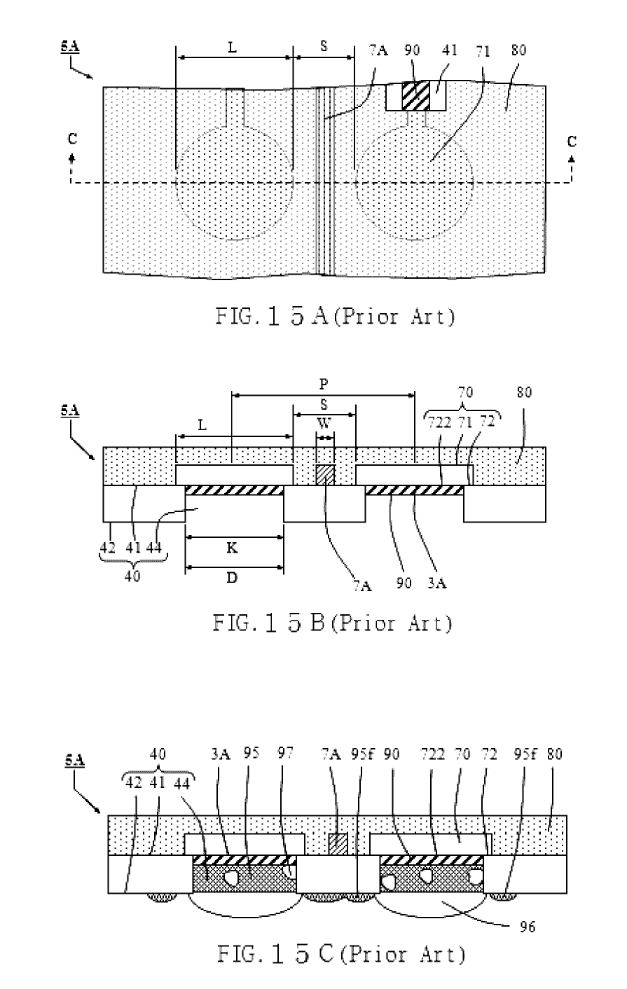

Please refer to FIGS. 1-1 to 1-3, they are shown the structure of printed circuit board 50 and the steps which are related to the first trace 70 of printed circuit board 50 electrically connected to the first conductive pad 30 of printed circuit board 50. FIG. 1-1 is a bottom view of the printed circuit board 50. FIG. 1-2A is a cross-sectional view of FIG. 1-1 along line C-C. FIG. 1-2B is another bottom view along line C-C. FIG. 1-3 is a cross-sectional view of the printed circuit 50 with a blind via 44. Firstly, please refer to FIGS. 1-1, 1-2A, and 1-2B, the printed circuit board 50 comprises two first traces 70, a first insulator 40, two second traces 7A, a solder mask 80, two first conductive pads 30, and a protective layer 90. Each of the first trace 70 may be made of copper, metal or other suitable conductors and has a first side edge 73, an upper surface 71, and a lower surface 72. A portion of the lower surface 72 is employed as a second lower surface 722, in this manner, said first trace 70 having a second lower surface 722 which is a portion of the lower surface 72 of first trace 70. at least a portion of the upper surface 71 of each first trace 70 is provided for electrically connecting with conductive elements such as a tin material, a wire, a bump, a lead, a solder ball, a conductive layer, an another trace, or other suitable conductor(s). The first insulator 40 includes an upper surface 41, a lower surface 42, and a predetermined blind via area 46 (shown with dashed line) which is comprised of an obstructer 40k, said obstructer 40k is received in said predetermined blind via area 46 and is formed by a portion of the first insulator 40. In this manner, said predetermined blind via area 46 is solid, said obstructer 40k is coupled with said second lower surface 722 of first trace 70 temporarily, and said obstructer 40k received in said predetermined blind via area 46 of first insulator 40 is prepared (ready) for being removed from said predetermined blind via area 46 of first insulator 40, meanwhile, the second lower surface 722 of first trace 70 is used for being electrically connected to a conductive material, wherein at least a portion of said conductive material being exposed to the atmosphere eventually, Once the predetermined blind via 46 becomes a blind via (numeral 44, refer to FIG. 1-3) which is penetrated through the first insulator 40, then, the second lower surface 722 of first trace 70 enables to be received in the blind via 44 of first insulator 40 and exposed to the atmosphere for being electrically connected to an external connection (such as a tin material, a wire, a bump, a lead, a solder ball, a conductive layer, an another trace, or the like) which is exposed to the atmosphere, The predetermined shape of the predetermined blind via area 46 may be circle, rectangular, and square, but not limited thereto, wherein a portion of said predetermined blind via area 46 of said first insulator 40 enables to protrude the side edge 33 of said first conductive pad 30 as demanded (the advantages of predetermined blind via area 46 of first insulator 40 protruding the side edge 33 of first conductive pad 30, refer to the descriptions of FIG. 6C-1). The first trace 70 is arranged at the upper surface 41 of the first insulator 40. The lower surface 72 of the first trace 70 is bonded to the first insulator 40. The predetermined blind via area 46 of the first insulator 40 is arranged corresponding to the second lower surface 722 of the first trace 70 and the obstructer 40k of the predetermined blind via area 46 is coupled with said second lower surface 722 of first trace 70 so that the second lower surface 722 of the first trace 70 is not exposed to the atmosphere. Each of the second trace 7A is arranged at the upper surface 41 of the first insulator 40 and located between the two first traces 70. Said solder mask 80 is situated on both said upper surface 41 and the upper surface 71 of first trace 70, wherein at least a portion of the upper surface 71 of the first trace 70 is not covered by the solder mask 80 in order to be exposed to the atmosphere for being electrically connected to the external connection such as tin, nickel, conductive wire, conductive bump, conductive layer, solder ball, solder paste, or other suitable conductors. The solder mask 80 may be designed as demanded. Each of the first conductive pads 30 may be made of copper, metal or other conductors. The two first conductive pads 30 are arranged at the lower surface 42 of the first insulator 40. At least a portion of the first conductive pad 30 is arranged corresponding to the lower surface 72 of the first trace 70. The first conductive pad 30 includes a side edge 33, an upper surface 31, and a lower surface 32. The first conductive pad 30 shown as in FIG. 1-2A has an opening 34 which is penetrated through said first conductive pad 30, at least a portion of the opening 34 is arranged corresponding to the second lower surface 722 of the first trace 70. An object received in the opening 34 is formed by a portion of the first insulator 40. The first insulator 30 shown as in FIG. 1-2B has a predetermined opening 36 (shown as the dashed line). An object received in the predetermined opening 36 is formed by a portion of the first conductive pad 30. The printed circuit board 50 of the present invention may be selected from either the first conductive pad 30 of FIG. 1-2A or the first conductive pad 30 of FIG. 1-2B. The lower surface 32 and the side edge 33 of the first conductive pad 30 are both bonded to the first insulator 40 so that the upper surface 31 of the first conductive pad 30 is exposed out of the lower surface 42 of the first insulator 40 and the upper surface 31 of the first conductive pad 30 may be flatly, concavely, or convexly arranged at the lower surface 42 of the first insulator 40. The protective layer 90 (shown as in FIG. 1-1) is only arranged at the portion of the upper surface 71 of the first trace 70 which is exposed to the atmosphere. Please refer to FIG. 1-3, after finishing the process shown in FIG. 1-2A or FIG. 1-2B, a process of drilling (not shown) which is mechanical, laser-like, or chemical is provided so as to make the predetermined blind via area 46 become a blind via 44 which is penetrated through the first insulator 40, wherein all of the obstructers in said predetermined via area 46 associated with the openings 34, the predetermined opening 36 are removed respectively, and the predetermined opening 36 of first conductive pad 30 also becomes an opening 34 which is a through hole, then the opening 34 of first conductive pad 30 is corresponding to the blind via 44 of first insulator 40, and the blind via 44 of the first insulator 40 is arranged corresponding to the second lower surface 722 of the first trace 70 so that the second lower surface 722 of the first trace 70 is received in the blind via 44 of the first insulator 40 and is exposed to the atmosphere for being electrically connected to a conductive material (such as a tin, nickel, conductive wire, conductive bump, conductive layer, solder ball, solder paste, or other suitable conductors), wherein at least a portion of said conductive material being exposed to the atmosphere, and a predetermined shape of the blind via 44 may be circle, rectangular, or square, but not limited thereto. Meanwhile, the area of predetermined shape of said real via 44 of first insulator 40 may be equal to the area of the second surface 722 of first conductive trace 70; Accordingly, the second lower surface 722 of the first trace 70 is exposed to the blind via 44, The opening 34 of the first conductive pad 30 in FIG. 1-2A may be performed by removing an obstructer arranged inside thereof before the predetermined blind via area 46 becomes the blind via 44. The predetermined opening 36 of the first conductive pad 30 in FIG. 1-2B may be performed by removing an obstructer arranged inside thereof so as to become the opening 34 before the predetermined blind via area 46 becomes the blind via 44. According to above descriptions and the four designs of the printed circuit board 5A in FIGS. 15A to 15C, it shows that the printed circuit board 50 is better than the printed circuit board 5A. The reasons are described as follows. Firstly, the quantities of the second traces 7A may be increased. The widths of the first conductive pad 30 and the first conductive pad 3A of the printed circuit board 5A are both equal to 250 μm, the width Da of the predetermined blind via area 46 of the first insulator 40 in FIG. 1-2A is smaller than the width K of the first conductive pad 30 because the first conductive pad 30 of the printed circuit board 50 is arranged at the lower surface 42 of the first insulator 40. In general, the width Da of the predetermined blind via area 46 is ranged between 65 μm and 200 μm. In order to prevent the first trace 70 from dropping into the blind via 44 (shown as in FIG. 1-3), the width L of the two first traces 70 arranged corresponding to the predetermined blind via area 46 is wider than the width Da of the predetermined blind via area 46 about 100 μm, then the width L of first trace 70 is between 165 μm and 300 μm, in case that the width L of first trace 70 is 250 μm. The smallest distance S between the two first traces 70 is 250 μm so that the area between the two first traces 70 may be received the two second traces 7A (50+50+50+50+50=250 μm). Compared to the printed circuit board 5A, the printed circuit board 50 may be arranged one more second trace 7A. Secondly, the cost of the protective layer 90 is reduced. The second lower surface 722 of the first trace 70 is not exposed to the atmosphere while the protective layer 90 is arranged so that the protective layer 90 is not bonded to the second lower surface 722 of the first trace 70 and further the usage of quantities and the cost of the protective layer 90 may be reduced. Thirdly, the bonding strength of the conductive material and the first conductive pad 30 may be enhanced, because a first conductive material 95 may be bonding to both the second lower surface 722 of the first trace 70 and the upper surface 31 of the first conductive pad 30 due to the first conductive material 95 filled into the blind via 44 of the first insulator 40, the bonding area and strength of the first conductive pad 30 may be enhanced through a side wall 35 (shown as in FIG. 1-3) of the opening 34 of the first conductive pad 30 and further the quality of the printed circuit board may be improved. Fourthly, nowadays, the size of the development trend of the electronic devices is light, thin, short, and small shown as in FIG. 1-2A. In case that the thickness T of the first insulator 40 is smaller than 100 μm, the rigidity may be increased to prevent the first insulator 40 from being bent and broken to damage because the predetermined blind via area 46 has not become the blind via 44 yet, so that the first insulator 40 is still a whole complete insulator without any through hole (i.e. blind via). At the same time, even when the quantities of the blind vias are more, it may also prevent the first insulator 40 from being bent and broken to damage. In general, when the thickness T of the first insulator 40 is smaller than 100 μm and the width D (shown as in FIG. 1-3) of the blind via 44 is equal to 200 μm, that is, the ratio of the thickness T of the first insulator 40 to the width Da (shown as in FIG. 1-2A) of the predetermined blind via area 46 is not lager than 0.5 (i.e. equal to or smaller than 0.5; T/Da≦0.5), it is easy to be bent and broken to damage because the rigidity of the first insulator 40 is not enough. The rigidity of the first insulator 40 may be increased to reduce or prevent from above mentioned problems by increasing the thickness T of the first insulator 40 or arranging the predetermined blind via area 46 at the first insulator 40. However, the materials and the manufacturing cost may be needed more to increase the thickness T of the first insulator 40 and it is not good to the development trend of electronic industries. Nevertheless, in case that the first insulator 40 has the predetermined blind via area 46, the rigidity of the first insulator 40 may be increased while the thickness T is not changed. Therefore, it may prevent from using more materials and further prevent the first insulator 40 from being bent and broken to damage, and it also fits the development trend of electronic industries. When the first insulator 40 has the predetermined blind via area 46, the ratio of the thickness T of the first insulator 40 to the width Da of the predetermined blind via area 46 is not larger than 0.5 (T/Da≦0.5, or smaller than 0.4, or between 0.30 and/or 0.01 etc.), it may reduce or prevent the first insulator 40 from being bent and broken to damage. wherein in case that said predetermined blind via 46 of first insulator 40 having a plurality of widths Da with different dimensions, then the width Da of said predetermined blind via 46 of first insulator 40 herein is the largest one; Moreover, as shown in FIG. 1-3, in case that the predetermined blind via area 46 has already been become the blind via 44, then the ratio of the thickness T of the first insulator 40 to the width D of the blind via area 44 also enables to be not larger than 0.5 (T/D≦0.5), in this manner, the printed circuit board 50 may be more practical, wherein the width D of blind via 44 is equal to (or close to) the width Da of predetermined blind via 46; Additionally, the upper surface or the lower surface of the printed circuit board of the present invention (such as the surface of the first insulator 40 exposed to the atmosphere) may be connected with the carrier sheet(s) (numbered as 85, 88, shown as in FIG. 14A) or the printed circuit board may be not arranged the first conductive pad 30 (shown as in FIGS. 4-1 to 5) so as to make the printed circuit board more practical.

Please refer to FIG. 2-1, it shows a cross-sectional view of the printed circuit board 51. The structure and the numbers of the printed circuit board 51 are almost the same as them of the printed circuit board 50 shown in FIG. 1-2A. The difference therebetween is described as follows. The printed circuit board 51 has a plurality of predetermined vent areas 48 which are arranged at the peripherals of the predetermined blind via areas 46 of the first insulator 40 and located adjacent to the predetermined blind via areas 46 respectively. That is, each predetermined blind via area 46 further includes the predetermined vent areas 48, wherein each predetermined vent area 48 is comprised of an obstructer 40m, said obstructer 40m is received in said predetermined vent area 48 and is formed by a portion of the first insulator 40. In this manner, each predetermined vent 48 is solid, each predetermined vent area 48 of the first insulator 40 is arranged corresponding to the second lower surface 722 of the first trace 70, and each obstructer 40m of the predetermined vent area 48 is coupled with said second lower surface 722 of first trace 70 too.

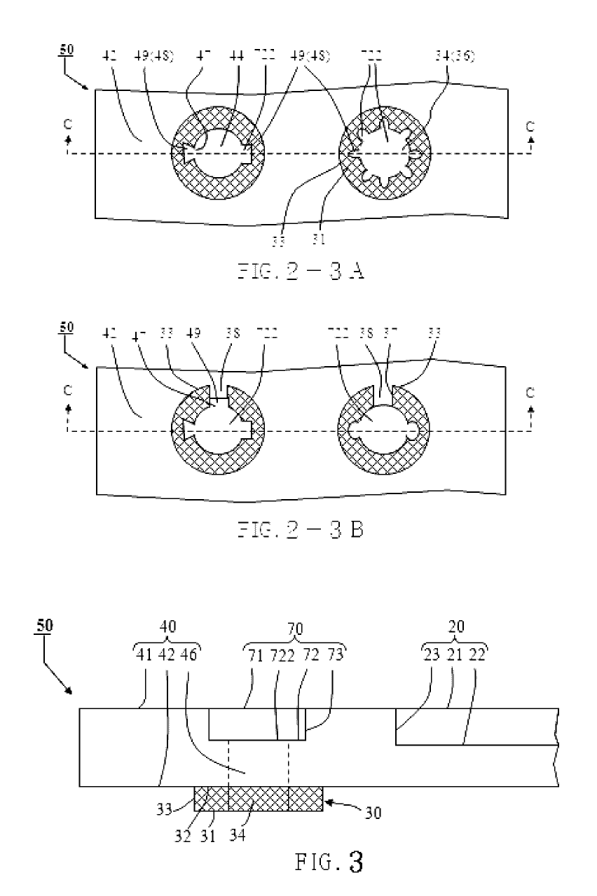

Please refer to FIGS. 2-2, 2-3A, and 2-3B, FIGS. 2-3A and 2-3B are the bottom views of the printed circuit board 50, and FIG. 2-2 is the cross-sectional view of FIG. 2-3A or 2-3B along line C-C. The descriptions are as follows. The printed circuit board 50 in FIG. 2-2 is operated by providing a process of drilling (not shown) after the printed circuit board 51 in FIG. 2-1 is finished. By the process of drilling, the objects arranged in the predetermined blind via area 46 and the predetermined vent area 48 are removed so that both the predetermined blind via area 46 becomes the blind via 44 and the predetermined vent area 48 becomes the vent 49 which is penetrated through the first insulator 40, in this manner, said vent 49 is a through hole. The shape of blind via 44 associated with the vent 49 is the same as the shape of the predetermined blind via area 46 associated with the predetermined vent area 48 (refer to FIG. 2-3A or FIG. 2-3B). Furthermore, the first insulator 40 of the printed circuit board 50 further includes the vent(s) 49 and the gate(s) 47. The gate 47 is arranged between the blind via 44 and the vent(s) 49 so that the blind via 44 is fluidly communicated with the vent(s) 49. The blind via 44 further includes the vent(s) 49 and the gate 47. A portion of the second lower surface 722 of the first trace 70 is exposed to the blind via 44 and the other part thereof is exposed to the vent(s) 49. Please refer to FIGS. 6A-1 to 6C-2 (the cross-sectional view along line C-C), a portion of the first insulator 40 is arranged between the first trace 70 and the vent(s) 49 as demanded, in this manner, the vent 49(s) in FIG. 6A-1 to FIG. 6c-2 is not penetrated. In FIG. 2-3A, the peripheral of the blind via 44 may have one or more vents 49. At least a portion of the vent(s) 49 is arranged corresponding to the opening 34 of the first conductive pad 30. Besides the gate 47 may provide the gas or chemical solvents in the blind via 44 to flow into the vent(s) 49, it may also limit the conductive material flowed into the vent(s) 49 by changing the width of the gate 47 so as to increase the quality of the printed circuit board 50. Especially, when the conductive material includes solder paste with tin particles or other metals, the effects of the gate 70 may be effectively appeared. For example, in case that the diameter of the tin particle in the solder paste is 75 μm, the width of the gate 47 may be designed to smaller than 70 μm or much smaller so that the tin particle with 75 μm diameter may be limited in the blind via 44 by the gate 47 and the gas (numbered as 97 in FIG. 15C) or the chemical solvents may be only flowed into the vent(s) 49. Accordingly, when the printed circuit board 50 is heated, the gas or the chemical solvents sealed in the blind via 44 of the insulator 40 may be passed through the gate 47, the vent(s) 49 of the first insulator 40, and the lower surface 42 of the first insulator 40 to directly exhaust to the atmosphere. Therefore, the gas sealed in the blind via 44 may be effectively reduced and the quantities of the tin particles which are forced out of the blind via 44 due to the expanding gas are effectively reduced. And further, it may prevent the tin materials from dropping onto the lower surface of the printed circuit board 50 to result in the damage of short circuit. The reason is the volume of the gas may be obviously increased by heating. If the time of the gas stayed in the blind via 44 of the first insulator 40 is longer, the volume of the gas is larger and the pressure in the blind via 44 of the first insulator 40 is higher. Therefore, the tin particles in the solder paste may be forced out of the blind via 44 of the first insulator 40 and then dropped onto the surface of the printed circuit board 50 so as to result in the damage of short circuit of the printed circuit board 50. Moreover, said blind via 44 of first insulator 40 of printed circuit board 50 in FIG. 2-3A further having both a width D1 and a length H (the advantages of said width D1 and said length H are described in the descriptions of FIG. 7B-1 to FIG. 7B-3), wherein said width D1 of blind via 44 is shorter than said length H of blind via 44; The difference of the bottom view in FIG. 2-3B and the bottom view in FIG. 2-3A is the first conductive pad 30. The first conductive pad 30 in FIG. 2-3B includes a groove 38 and a groove wall 37. The groove 38 is passed through the first conductive pad 30 so that the first conductive pad 30 is not closed. A portion of the first insulator 40 is received in the groove 38 and bonded to the groove wall 37. The object received in the groove 38 is formed by a portion of the first insulator 40. If the vent(s) 49 is needed, the size of the vent(s) 49 may be designed as demanded and then the object received in the groove 38 is partially or totally removed so that the vent(s) 49 may be more elastic. In FIGS. 2-3A and 2-3B, the opening 34(36) of the first conductive pad 30 may be a predetermined shape, such as circle, rectangular, and square, but not limited thereto, Besides, according to the descriptions of FIGS. 2-1,2-2 and 2-3A, The predetermined blind via area 46 also having a width D1 and a length H, said width D1 of predetermined via area 46 is shorter than said length H of predetermined via area 46; In addition, the first conductive pad 30 shown in FIG. 2-3B is made of a conductive metal and is not closed, in this manner, a portion of the vent 49 of said first conductive pad 30 may be able to protrude the side edge 33 of first conductive pad 30, then the area of said vent 49 may be able to get larger, as this result, it is good for said vent 49 to be effectively exhausting the gas or chemical solvent in the blind via 44 and further preventing from damage of short circuit.

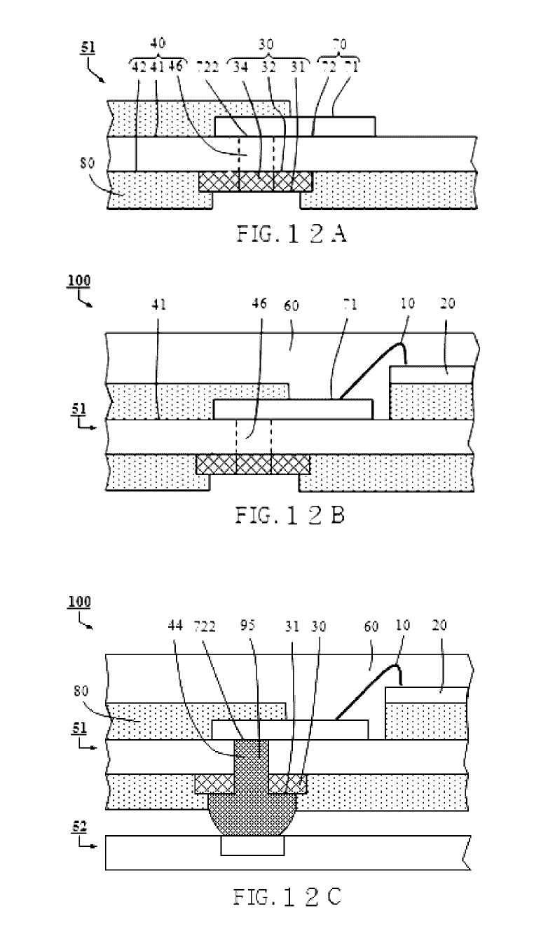

Please refer to FIG. 3, it shows the cross-sectional view of the printed circuit board 50. The printed circuit board 50 comprises the first trace 70, the first insulator 40, the first conductive pad 30, and a member 20 (such as the electronic element). The first trace 70 has the first side edge 73, the upper surface 71, and the lower surface 72. A portion of the lower surface 72 is employed as a second lower surface 722. A portion of the upper surface 71 of each first trace 70 is provided for electrically connecting with conductive element(s). The first insulator 40 includes the upper surface 41, the lower surface 42, and the predetermined blind via area 46. The predetermined blind via area 46 is formed by a portion of the first insulator 40. The first trace 70 is arranged at the upper surface 41 of the first insulator 40. At least a portion of the first side edge 73 of the first trace 70 and the lower surface 72 of the first trace 70 are bonded to the first insulator 40. The upper surface 71 of the first trace 70 is exposed out of the upper surface 41 of the first insulator 40. The predetermined blind via area 46 is both arranged corresponding to the second lower surface 722 of first trace 70 and coupled with said second lower surface 722 of first trace 70 so that the second lower surface 722 of the first trace 70 is not exposed to the atmosphere. The predetermined blind via area 46 of the first insulator 40 becomes a real blind via (numbered as 44 in FIG. 1-3) through a process of drilling so that the second lower surface 722 of the first trace 70 may be exposed to the blind via 44. The predetermined blind via area 46 may further include a predetermined vent area (numbered as 48 in FIG. 2-1). The first conductive pad 30 is arranged at the lower surface 42 of the first insulator 40. At least a portion of the first conductive pad 30 is arranged corresponding to the lower surface 72 of the first trace 70 and the first conductive pad 30 may include the side edge 33, the upper surface 31, the lower surface 32, and the opening 34. The lower surface 32 is bonded to the first insulator 40. The opening 34 of the first conductive pad 30 may be designed the predetermined opening area (numbered as 36 in FIG. 1-2B) as demanded. The member 20 may be employed as a chip, flip chip, and/or semiconductor package, but not limited thereto. The member 20 may include an upper surface 21, a lower surface 22, and a side edge 23. The upper surface 21 having a plurality of conductive terminal/pad (not shown) for external connection such as a conductive wire and/or conductive bump etc., The member 20 may be electrically connected with the printed circuit board 50 through a conductive mean (numbered as 10 in FIG. 12B). The member 20 is arranged at the upper surface 41 of the first insulator 40. At least a portion of the side 23 and the lower surface 22 are coupled with the first insulator 40. Accordingly, the upper surface 21 of the member 20 may be flatly, concavely, or convexly arranged at the upper surface 41 of the first insulator 40 as demanded. Besides, the first trace 70 may be coupled with the first insulator 40 through both the lower surface 72 and at least a portion of the first side edge 73 of the first trace 70 so that the upper surface 71 of the first trace 70 may be flatly, concavely, or convexly arranged at the upper surface 41 of the first insulator 40. Otherwise, at least a portion of the side edge 33 of the first conductive pad 30 is coupled with the first insulator 40 so that the upper surface 31 of the first conductive pad 30 may be flatly, concavely, or convexly arranged at the lower surface 42 of the first insulator 40. Moreover, The peripheral of the predetermined blind via area 46 of the first insulator 40 may be arranged the predetermined vent area 48 or blind via 44 the predetermined blind via area 46 is replaced by the blind via 44, or the vent 49 is replaced by the predetermined vent area 48; Furthermore, the member 20 may be coupled with the insulator 40 by the side edge 23 of member 20 exclusively, in this manner, the lower surface 22 of member 20 enables to be exposed out of the lower surface 42 of first insulator 40 so as to enhance the dissipation of heat generated by said member 20.

Please refer to FIGS. 4-1 to 4-2, they show the cross-sectional views of the printed circuit boards 50, 51. The printed circuit boards 50, 51 have the effects of the vent(s) 49 to prevent the printed circuit board 5A in FIG. 15C from the damage of short circuit. The printed circuit board 50 in FIG. 4-1 comprises the first trace 70, the first insulator 40, and a carrier sheet (numbered as 85 with dashed line). The first trace 70 includes the first side edge 73, the upper surface 71, and the lower surface 72. A portion of the lower surface 72 is employed as a second lower surface 722. At least a portion of the upper surface 71 of the first trace 70 may be provided for electrically connecting with conductive elements. The first insulator 40 includes the upper surface, the lower surface 42, and the predetermined blind via area 46. The predetermined blind via area 46 may further include a predetermined vent area 48. The predetermined blind via area 46 and the predetermined vent area 48 are respectively formed by a portion of the first insulator 40. The first trace 70 is arranged at the upper surface 41 of the first insulator 40. The first insulator 40 is bonded to the lower surface 72 of the first trace 70. The predetermined blind via area 4 of the first insulator 40 is arranged corresponding to the second lower surface 722 of the first trace 70 so that the second lower surface 722 of the first trace 70 is not exposed to the atmosphere. The predetermined vent area 48 is arranged adjacent to the predetermined blind via area 46. The carrier sheet 85 may be arranged at the lower surface 42 of the first insulator 40 as demanded so as to increase the rigidity of the printed circuit board 50. At the same time, the carrier sheet 85 may have an opening 84 which is a through hole, wherein the width of said opening 84 enables to be either larger than 5 μm or smaller than 10,000 μm as demanded. Accordingly, a portion of the lower surface 42 of the first insulator 40 is exposed to the opening 84. The opening 84 of the carrier sheet 85 is arranged corresponding to the predetermined blind via area 46. Otherwise, the opening 84 of the carrier sheet 85 is not arranged corresponding to the predetermined blind via area 46. Wherein either the carrier sheet 85 enables to be removed before the conductive material is provided (shown as in FIGS. 4-2; FIG. 14B and FIG. 14 C) or said carrier sheet 85 enables to be removed or not be removed from said printed circuit board 50,51 in any suitable time (step) as demanded, and the carrier sheet 85 may not include the opening 84. Next, in FIG. 4-2, a process of drilling (not shown) is provided to the printed circuit board 51 after the printed circuit board 50 in FIG. 4-1 is finished. Wherein the obstructer received in said predetermined blind via area 46 and the predetermined vent area 48 are all removed, then The predetermined blind via area 46 and the predetermined vent area 48 are respectively become the blind via 44 and the vent 49 by the process of drilling. The blind via 44 of the first insulator 40 further includes the vent 49 and the gate (numbered as 47 in FIG. 2-3A). The second lower surface 722 of the first trace 70 is exposed to both the blind via 44 and the vent 49. The carrier sheet 85 is removed and then a first conductive material 95 is provided. The first conductive material 95 is bonded to the second lower surface 722 of the first trace 70. Wherein at least a portion of the first conductive material 95 is received in the blind via 44 of the first insulator 40 and bonded to the second lower surface 722 of the first trace 70 so that the first conductive material 95 is electrically connected with the first trace 70 of the printed circuit board 51. The first conductive material 95 is received in the blind via 44 and bonded to the second lower surface 722 of the first trace 70 by a suitable machine (such as wire blonder). The first conductive material 95 may shorten a distance between the second lower surface 722 of the first trace 70 and the lower surface 42 of the first insulator 40 so that the second lower surface 722 received in the blind via 44 is easier to electrically connect to the outside (such as tin, nickel, conductive wire, conductive bump, lead, solder ball, or other suitable conductors) and further the damage of open circuit of the printed circuit board 51 may be prevented. The first conductive material 95 may be employed as a conductive bump, such as copper bump, gold bump, and/or alloy bump, but not limited thereto. Furthermore, the upper surface (not numbered) of the first conductive material 95 may be stacked one or more conductive bumps (not shown) so as to adjust the distance between the second lower surface 722 of the first trace 70 and the lower surface 42 of the first insulator 40. The first conductive material 95 may be employed as the conductive material (reference to the descriptions of FIG. 14C) as demanded. The preferred embodiment of FIG. 4-2 is that the carrier sheet 85 is removed from the first insulator 40 after the predetermined blind via area 46 and the predetermined vent area 48 are respectively become the blind via 44 and the vent 49 before the first conductive material 95 is provided as demanded. The carrier sheet 85 in FIG. 4-2 may be removed from the first insulator 40 after the member 20 and the encapsulant 60 (reference to the descriptions of FIGS. 14A to 14C) are arranged at one surface of the printed circuit board 50 and before the first conductive material 95 is provided as demanded. Besides, the first trace 70 may (or not) include a second side 732. The second side 732 is arranged between the lower surface 72 and the second lower surface 722. In this manner, the second lower surface 722 is concavely arranged at the lower surface 72 of the first trace 70. Then the area of the first trace 70 exposed to the blind via 44 may be increased due to the arrangement of the second side 732 so that the bonding strength between the first conductive material 95 received in the blind via 44 and the first trace 70 may be increased and the quality of the printed circuit board 51 may be improved. In FIG. 4-1, the printed circuit board 50 may not include the predetermined vent area 48 as demanded. Accordingly, the blind via 44 of the printed circuit board 51 in FIG. 4-2 may not include the vent 49; wherein the carrier sheet 85 in FIG. 4-1 is optional, meanwhile, it may not be necessary for said carrier sheet 85 to be removed from the printed circuit board 50 either.

Please refer to FIG. 5, it shows the cross-sectional view of the printed circuit board 51. The characteristics and the numbers of the printed circuit board 51 are almost the same as them of the printed circuit board 50 in FIG. 4-1. The difference therebetween is described as follows. At least a portion of the first side edge 73 of the first trace 70 is bonded to the first insulator 40 so that the upper surface 71 of the first trace 70 may be flatly, concavely, or convexly arranged at the upper surface 41 of the first insulator 40. Accordingly, the thickness of the printed circuit board 51 may be thinner and more practical. The printed circuit board 51 may not include the predetermined vent area 48 but include the carrier sheet 85 (shown as in FIG. 4-1). The carrier sheet 85 is arranged at one surface of the printed circuit board 51 (such as the lower surface 42 of the first insulator 40). The carrier sheet 85 has the opening 84 so that a portion of the lower surface 42 of the first insulator 40 may be exposed to the opening 84 of carrier sheet 85. The opening 84 of the carrier sheet 85 is arranged corresponding to the predetermined blind via area 46. Accordingly, a process of electrically connecting the first trace 70 with the first conductive material 95 may be provided and the steps are described as follows. Firstly, the member 20 and the encapsulant 60 (shown as in FIG. 12B) are provided. The member 20 and the encapsulant 60 are arranged at the same surface of the printed circuit board 51. The member 20 is arranged at the surface of the printed circuit board 51 so as to electrically connect the member 20 to the printed circuit board 51 (reference to the descriptions of FIG. 12B), and then the encapsulant 60 is covered at least a portion of the member 20. Secondly, a process of drilling is provided (not shown). Then the predetermined blind via area 46 is become the blind via 44 by the process of drilling so that at least a portion of the second surface 722 of the first trace 70 is exposed to the blind via 44. Thirdly, a process of peeling is provided to remove the carrier sheet 85 from the printed circuit board 51. Fourthly, the first conductive material 95 is provided. At least a portion of the first conductive material is received in the blind via 44 and bonded to the second lower surface 722 of the first trace 70 so that the first conductive material 95 is electrically connected to the first trace 70.

Please refer to FIGS. 6A-1 to 6C-2, FIGS. 6A-1, 6B-1, and 6C-1 are the bottom views of the three printed circuit board 50, 51, and 52 respectively, and FIGS. 6A-2, 6B-2, and 6C-2 are the cross-sectional views of FIGS. 6A-1, 6B-1, and 6C-1 respectively along lines B-B and C-C. Each of the three printed circuit board 50, 51, and 52 comprises the first trace 70, the first insulator 40, and the first conductive pad 30. The first trace 70 includes the first side edge 73, the upper surface 71, and the lower surface 72. A portion of the lower surface 72 is employed as the second lower surface 722. At least a portion of the upper surface 71 of the first trace 70 is provided for electrically connecting with suitable conductors. The first insulator 40 includes the upper surface 41, the lower surface 42, and the blind via 44. The first trace 70 is arranged at the upper surface 41 of the first insulator 40. In FIG. 6C-2, at least a portion of the first side edge 73 and the lower surface 72 of the first trace 70 of the printed circuit board 52 are bonded to the first insulator 40 so that the upper surface 71 of the first trace 70 is concavely arranged at the upper surface 41 of the first insulator 40. In FIGS. 6A-2 and 6B-2, the lower surface 72 of the first race 70 of each of the printed circuit boards 50, 51 is bonded to the first insulator 40 respectively. At the same time, please refer to the cross-sectional views of the printed circuit boards 50, 51, and 52 of the FIGS. 6A-2, 6B-2, and 6C-2 along line B-B, wherein a portion of the second lower surface 722 of the first trace 70 is exposed to the blind via 44 exclusively. Otherwise, please refer to the cross-sectional views of the printed circuit boards 50, 51, and 52 of the FIGS. 6A-2, 6B-2, and 6C-2 along line C-C, wherein a portion of the first insulator 40 is arranged between the bottom of the blind via 44 and the first trace 70, in this manner, the other portion of the second lower surface 722 of the first trace 70 is not exposed to the blind via 44. The first conductive pad 30 includes the side edge 33, the upper surface 31, and the lower surface 32, and the opening 34. The first conductive pad 30 is arranged at the lower surface 42 of the first insulator 40. At least a portion of the upper surface 31 of the first conductive pad 30 is provided for electrically connecting with suitable conductors. At least a portion of the side 33 and the lower surface 32 of the first conductive pad 30 in FIG. 6A-2 are bonded to the first insulator 40 so that the upper surface 31 of the first conductive pad 30 may be concavely arranged at the lower surface 42 of the first insulator 40. A portion of the lower surface 32 and the side edge 33 of the first conductive pad 30 in FIG. 6B-2 is bonded to the first insulator 40 so that the upper surface 31 of the first conductive pad 30 may be convexly arranged at the lower surface 42 of the first insulator 40. The lower surface 32 of the first conductive pad 30 in FIG. 6C-2 is bonded to the first insulator 40. According to above descriptions, when the first trace 70 or the first conductive pad 30 is arranged at one surface of the first insulator 40, then among at least a portion of the first side edge 73 of the first trace 70, at least a portion of the side edge 33 of the first conductive pad 30, or both the first trace 70 and the first conductive pad 30 are bonded to the first insulator 40 so that the upper surface 71 of the first trace 70 and/or the upper surface 31 of the first conducive pad 30 enables to be flatly, concavely, or convexly arranged at the surface of the first insulator 40 as demanded. In FIG. 6C-1, a portion of the bind via 44 protrudes the side edge 33 of the first conductive pad 30. The first conductive pad 30 comprised of a plurality of metals, then said blind via 44 is between said metals, wherein due to a portion of the bind via 44 protrudes the side edge 33 of first conductive pad 30, the area of blind via 44 enables not to be restricted in the area of first conductive pad 30 exclusively, then it allows said blind via 44 to be more practical, moreover, in case of said further having a vent (49), then the area of said vent 49 may be able to get larger, as this result, it is good for said vent (49) to be effectively exhausting the gas or chemical solvent in the blind via and further preventing from damage of short circuit. The first conductive pad 30 has a predetermined shape. The vent(s) (not shown) may be arranged at an area excluding the side edge 33 of the first conductive pad 30. The vent(s) may be fluidly communicated with the blind via 44. Then the blind via 44 further includes the vent(s). Accordingly, the printed circuit board of the present invention may be more practical. Otherwise, in FIG. 6A-1, the width of the opening 34 of the first conductive pad 30 is larger than the width of the blind via 44 so that a portion of the first insulator 40 enables to be received in the opening 34 of the first conductive pad 30 or a portion of the first insulator 40 enables to be not received in the opening 34 of the first conductive pad 30 as demanded. Otherwise, in FIGS. 6A-1 to 6C-1, the peripheral of the blind via 44 of each of the printed circuit boards 50, 51, 52 also enables to include the vent(s) 49 and the gate 47 to prevent the printed circuit board from damage of short circuit.

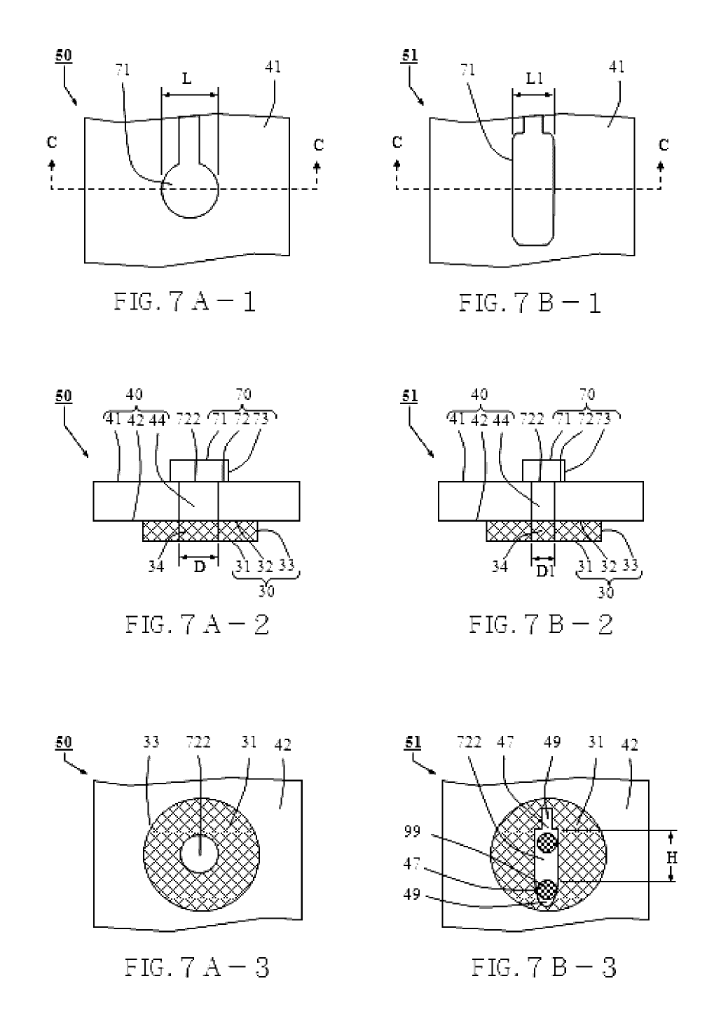

Please refer to FIGS. 7A-1 to 7B-3, FIGS. 7A-1 and 7B-1 are the top views of the printed circuit boards 50 and 51, FIGS. 7A-2 and 7B-2 are the cross-sectional views of FIGS. 7A-1 and 7B-1 along line C-C, and FIGS. 7A-3 and 7B-3 are the bottom views of the printed circuit boards 50, 51. Each of the printed circuit boards 50, 51 at least comprises the first trace 70, the first insulator 40, and the first conductive pad 30. The first trace 70 includes the first side edge 73, the upper surface 71, and the lower surface 72. A portion of the lower surface 72 is employed as the second lower surface 722. At least a portion of the upper surface 71 of the first trace 70 is provided for electrically connecting with the suitable conductors. The first insulator 40 includes the upper surface 41, the lower surface 42, and the blind via 44. The first trace 70 is arranged at the upper surface 41 of the first insulator 40. The lower surface 72 of the first trace 70 is bonded to the first insulator 40. The blind via 44 is arranged corresponding to at least a portion of the second lower surface 722 of the first trace 70 so that at least a portion of the second lower surface 722 of the first trace 70 may be exposed to the real blind 44. The first conductive pad 30 includes the side edge 33, the upper surface 31, and the lower surface 32. The first conductive pad 30 is arranged at the lower surface 42 of the first insulator 40. The lower surface 32 is bonded to the first insulator 40. At least a portion of the opening 34 of the first conductive pad 30 is arranged corresponding to the second lower surface 722 of the first trace 70. According to above descriptions and compared with the printed circuit boards 50, 51, another characteristic is appeared. The characteristic is to change the shape of the blind via 44 so as to reduce the width L of the first trace 70 and further to increase the distance S (shown as in FIG. 1-2A) between adjacent two first traces 70. Therefore, more second traces 7A (shown as in FIG. 1-2A) may be arranged between two first traces 70. In general, the shape of real blind vias 44 of the printed circuit boards 50 in FIGS. 7A-1 to 7A-3 which are drilled by the conventional mechanical or laser process are circle or close to circle. The aperture ratio thereof is not smaller than 0.97 or even smaller than 0.5. For example, when the blind via 44 is circle and the width D (shown in FIG. 7A-2) thereof is 100 μm, the aperture ratio of the blind via 44 (shown in FIG. 7A-3) is 1.0 (100/100), then the area of the said blind via 44 (i.e. the second lower surface 722 of the first trace 70) is 7,854 μm² (3.1416×(100/2)²). At the same time, in order not to make the first trace 70 drop into the blind via 44, the width L of the first trace 70 may need to be increased to 200 μm (50+100+50) or more as demanded. Next, the blind via 44 associated with the vent 49 of the printed circuit board 51 in FIGS. 7B-1 to 7B-3 have a predetermined shape (not circle), wherein For better understanding, the shape of the blind via 44 of first insulator 40 is assumed as a rectangle, in this manner, said blind via 44 of first insulator 40 of printed circuit board 51 having both a width D1 and a length H, wherein said width D1 of first blind via 44 of first insulator 40 is shorter than said length H of first blind via 44 of first insulator 40. The vent 49 allows a portion of the second lower surface 722 of the first trace 70 to be exposed to the vent 49 and received therein. At least a portion of the opening 34 of the first conductive pad 30 is arranged corresponding to the vent 49. The blind via 44 is arranged corresponding to at least a portion of the second lower surface 722 of the first trace 70. The aperture ratio thereof enables to be either smaller than 0.97 or further smaller than 0.5 and/or even smaller. For example, when the width D1 of the blind via 44 is 60 μm, in order to make the area of the bind via 44 of the printed circuit board 51 be not smaller than the area of the blind via 44 of the printed circuit board 50 to keep the bonding strength between the first trace 70 and the first conductive material 95, the length H of blind via 44 of first insulator 40 of the printed circuit board 51 is larger than 131 μm (7,854/60) so that the aperture ratio of the blind via 44 of the first insulator 40 (i.e. the aperture ratio of the width D1 to the length H of said blind via 44 of printed circuit board 51) is about 0.46 (60/131), wherein if the length H of said blind via 44 of printed circuit board 51 is larger than 131 μm, and the width D1 of said blind via 44 is still 60 μm, then the aperture ratio of said blind via 44 will be even smaller than 0.46, the aperture ratio of said blind via 44 may enable to be between 0.01 and 0.79. At the same time, in order to prevent the first trace 70 from dropping into the blind via 44, It is fine that the width L1 of the first trace 70 is increased to 160 μm. It will be fine too. In case of the width L1 of first trace 70 being larger than 160 μm, Accordingly, the blind via 44 of the printed circuit board 51 with small ratio may allow more first traces 70 to be coupled with the printed circuit board 51 so as to make the printed circuit board more practical. It is good for the electronic industries, and It is to be understood that a blind via 44 of first insulator 40 with both a real vent(s) 49 and a small ratio of the width D1 to the length H, then Not only allows the short circuit problem may be prevented but more first traces 70 may also be coupled with the first insulator 40 of printed circuit board 51. Besides, no matter what the shape of the vent 49 is oval or other suitable shapes, the gates 47 enable to limit the metal particles 99 of the conductive material to flow into the vent 49 so as to bring the effects of the gate 49 (reference to the descriptions of FIGS. 2-1 to 2-3B). In FIGS. 7B-2 and 7B-3, the real blind 44 of the printed circuit board 51 may be protruded the side edge 33 of the first conductive pad 30 (shown as in FIG. 6C-1). The one (or two) vent(s) 49 may be arranged at the area excluding the side edge 33 of the first conductive pad 30 as demanded. The predetermined blind via area 46 and the predetermined vent area 48 may be replaced by the blind via 44 and the vent 49 respectively as demanded, or the vent 49 is excluded, or the at least a portion of the side edges 73, 33 of the first trace 70 or the first conductive pad 30 is bonded to the first insulator 40.

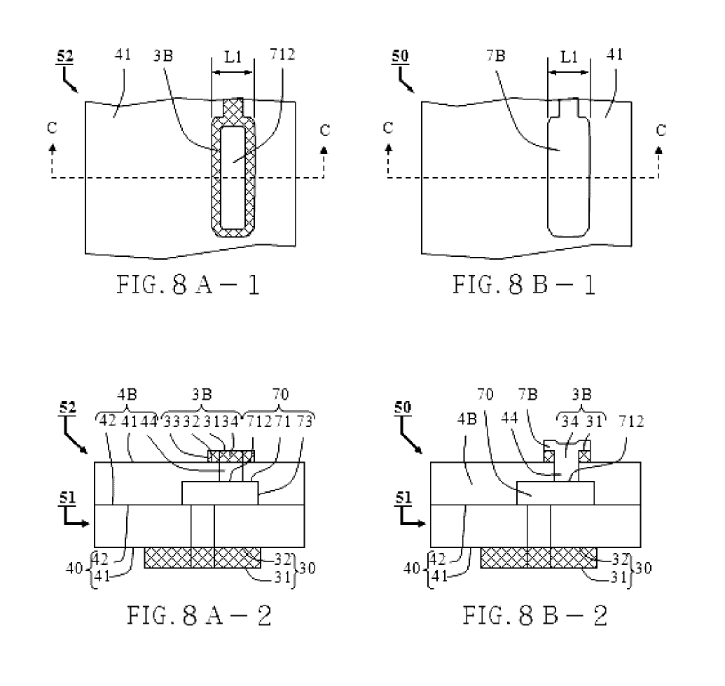

Please refer to FIGS. 8A-1 to 8B-2, the FIGS. 8A-1 and 8B-1 are the top views of the printed circuit boards 52 and 50, and FIGS. 8A-2 and 8B-2 are the cross-sectional views of FIGS. 8A-1 and 8B-1 along line C-C. The printed circuit board 52 comprises the printed circuit board 51, a second insulator 4B, and a second conductive pad 3B. The characteristics and numbers of the printed circuit board 51 may reference to the descriptions of FIGS. 7B-1 to 7B-3. The difference therebetween is that a portion of the upper surface 71 of the first trace 70 of printed circuit board 51 is employed as a second upper surface 712. The second insulator 4B includes an upper surface 41, a lower surface 42, and a blind via 44 which is penetrated through said second insulator 4B. The lower surface 42 of the second insulator 4B is bonded to the first insulator 40 of the printed circuit board 51 and covered the first trace 70. The second upper surface 712 of the first trace 70 is exposed to the blind via 44 of the second insulator 4B for bonding to the first conductive material 95, second conductive trace 7B (shown as in FIG. 8B-1), or other suitable conductors. The second conductive pad 3B includes a side edge 33, an opening 34 (i.e. a through hole), an upper surface 31, and a lower surface 32. The second conductive pad 3B is arranged at the upper surface 41 of the second insulator 4B blind via 44. The opening 34 of the second conductive pad 3B is arranged corresponding to the second upper surface 712 of the first trace 70 so that the second upper surface 712 of first trace 70 enables to be exposed to the opening 34 of second conductive pad 3B so as to be exposed to the atmosphere. The lower surface 32 is bonded to the second insulator 4B. Wherein at least a portion of the side edge 33 of the second conductive pad 3B also enables to be bonded to the second insulator 4B as demanded. The upper surface 31 of the second conductive pad 3B may be provided for electrically connecting with outside (tin, nickel, conductive wire, conductive bump, lead, solder ball, or other suitable conductors). The printed circuit board 50 is composed of the printed circuit board 52 and the second trace 7B. The second trace 7B is made of copper, nickel, or other suitable conductors. The second trace 7B may be arranged at the upper surface 31 of the second conductive pad 3B by electroplating or other suitable processes. A portion of the second trace 7B is received in both the blind via 44 of the second insulator 4B and the opening 34 of the second conductive pad 3B in order to electrically connect to the second upper surface 712 of the first trace 70 blind via 44. Accordingly, the second conductive pad 3B may be electrically connected with the first trace 70 through said second trace 7B. In order to make the bondability between the second trace 7B and a side wall (not numbered) of the blind via 44 of the second insulator 4B better, a seed layer (not shown) may be arrange between the second trace 7B and the second upper surface 712 of the first trace 70 and between the second conductive pad 3B and the side wall of the blind via 44 of the second insulator 4B. in this manner, said seed layer is between the second trace 7B and the second upper surface 712 of first trace 70 associated with the side wall of the blind via 44 of second insulator 4B, the side wall of the second conductive pad 3B and the upper surface 31 of second conductive pad 3B. According to above descriptions, the printed circuit board may further include at least one added insulator and an added conductive pad for stacking each element in order to become a multi-layer printed circuit board. The peripheral of the blind via 44 of the second insulator 4B may include the predetermined vent area 48 or the vent 49 shown as in FIGS. 2-1 to 7B-3. At least a portion of the second trace 7B of the printed circuit board 50 may be provided for electrically connecting with the member 20, the conductive means 10 (shown as in FIG. 11), and/or other suitable conductors.

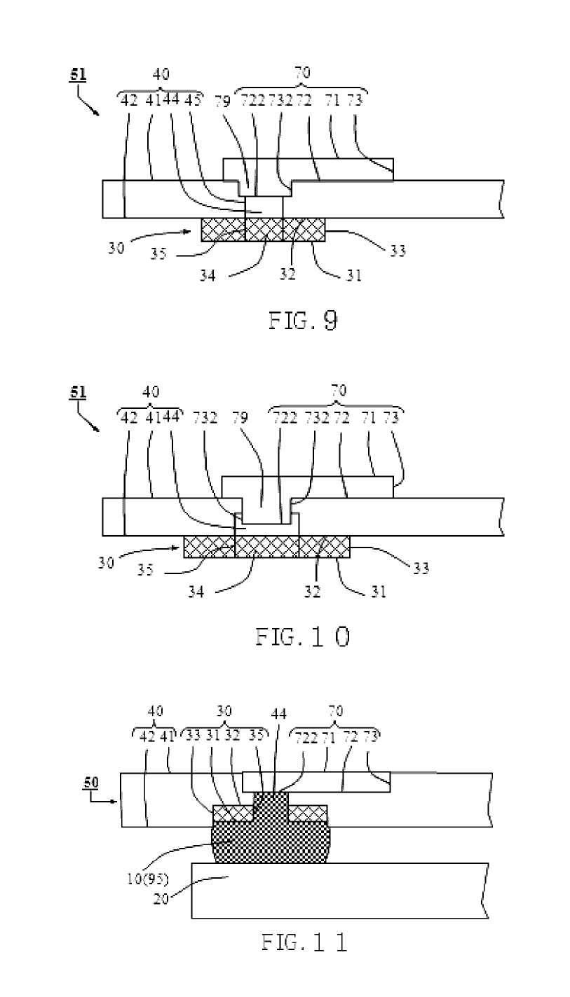

Please refer to FIGS. 9 and 10, they are the cross-sectional views of the printed circuit board 51. The characteristics and numbers of the first insulator 40, the first trace 70, and the first conductive pad 30 of the printed circuit board 51 are the same as the printed circuit board 50 in FIGS. 7A-1 to 7A-3 which may reference to the descriptions of FIGS. 7A-1 to 7A-3. The difference therebetween is described as follows. The first trace 70 includes the upper surface 71, the lower surface 72, the first side edge 73, and the second side edge 732. A portion of the lower surface 72 may be employed as the second lower surface 722. The second side edge 732 is arranged between the lower surface 72 and the second lower surface 722. The second lower surface 722 may be convexly arranged at the lower surface 72 and formed a protruding portion 79, or the second lower surface 722 is concavely (shown as in FIG. 4-2) arranged at the lower surface 72. The embodiment is described by the protruding portion 79 for example. The protruding portion 79 is made of the conductive material which is the same or not the same as the first trace 70. The protruding portion 79 may shorten the distance between the second lower surface 722 of the first trace 70 and the first conductive pad 30 so that the first conductive material 95 received in the blind via 44 may be easier to bond to and electrically connect with the second lower surface 722 of the first trace 70 and further prevent from damage of open circuit. In FIG. 9, the second side edge 732 of the first trace 70 is totally covered by the first insulator 40 so that at least a portion of the second lower surface 722 is exposed to the blind via 44 of the first insulator 40. In FIG. 10, at least a portion of the second side 732 is not covered by the first insulator 40 so as to exposed to the blind via 44 of the first insulator 40 and make at least a portion of the second lower surface 722 of the first trace 70 be exposed to the blind via 44. In FIG. 10, the second side 732 may be totally exposed to the blind via 44 as demanded.

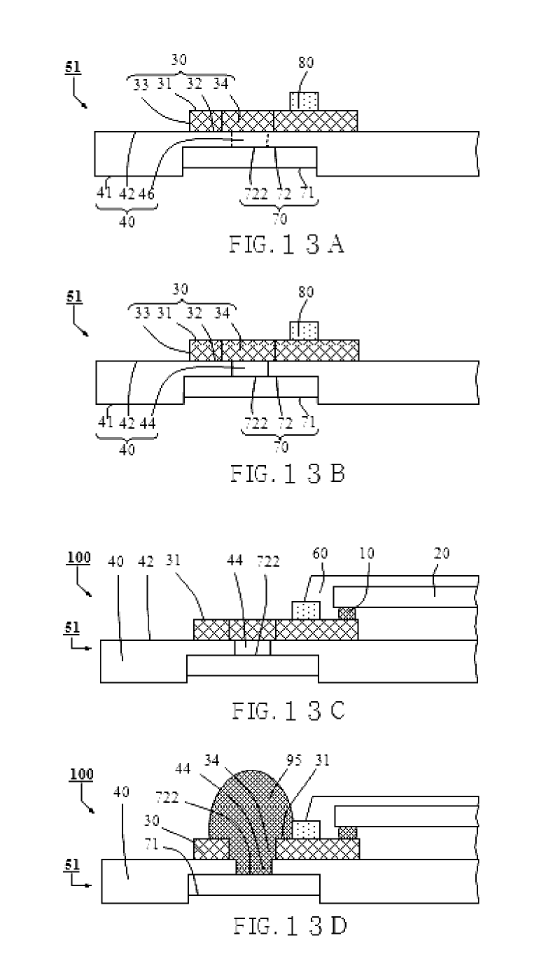

Please refer to FIG. 11, it shows the cross-sectional view of the printed circuit board 50 which is combined with the member 20. The printed circuit board 50 comprises the first trace 70, the first insulator 40, the first conductive pad 30, and the member 20. The first trace 70 includes the upper surface 71, the lower surface 72, and the first side edge 73. A portion of the upper surface 71 of the first trace 70 may be provided for electrically connecting with the suitable conductors. A portion of the lower surface 72 is employed as the second lower surface 722. The first insulator 40 includes the upper surface 41, the lower surface 42, and the blind via 44. The first trace 70 is arranged at the upper surface 41 of the first insulator 40. At least a portion of the side edge 73 and the lower surface 72 of the first trace 70 are bonded to the first insulator 40 so that the upper surface 71 of the first trace 70 may be flatly, concavely, or convexly arranged at the upper surface 41 of the first insulator 40. The blind via 44 is arranged corresponding to the second lower surface 722 of the first trace 70 so that the second lower surface 722 of the first trace 70 may be exposed to the blind via 44. The first conductive pad 30 is arranged at the lower surface 42 of the first insulator 40 and includes the side edge 33, the upper surface 31, the lower surface 32, the opening 34, and the side wall 35. A portion of the upper surface 31 may be provided for electrically connecting with the suitable conductors. The opening 34 is arranged corresponding to the second lower surface 722 of the first trace 70. At least a portion of the side edge 33 and the lower surface 32 are bonded to the first insulator 40 so that the upper surface 31 of the first conductive pad 30 may be flatly, concavely, or convexly arranged at the lower surface 42 of the first insulator 40. The member 20 is arrange at the lower surface 42 of the first insulator 40 and connected with the printed circuit board 50 through the conductive mean 10 (95). When the member 20 is employed as a flip chip, the conductive mean 10 may be employed as a conductive bump. Nevertheless, in case that the member 20 is employed as either a semiconductor package, module, or other suitable members, then the conductive mean 10 may be employed as a solder ball, solder paste, or other suitable conductors which are also one kind of the first conductive material 95. The conductive mean 10 (95) is arranged between the member 20 and the printed circuit board 50. A portion f the conductive mean 10 is received in the blind via 44 of the first insulator 40. The printed circuit board 50 is bonded to and electrically connected with the member 20, the second lower surface 722 of the first trace 70, and the first conductive pad 30 through the conductive means 10 (95). Besides, the encapsulant 60 (shown as in 13B) may be arranged at the surface of printed circuit board 50 and at least covered a portion of the member 20 to protect the member 20 as demanded. If the member 20 employed as a semiconductor package (numbered as 100 shown in FIG. 12B and/or FIG. 13C), then the member 20 further having at least a chip and/or a flip chip.

It is known by each printed circuit board in FIGS. 1-1 to 11 that the structure mainly comprises the first trace 70, the first insulator 40, and/or the first conductive pad 30. No matter what the first side edge 73 of the first trace 70 and/or the side edge 33 of the first conductive pad 30 in FIGS. 1-1 to 11 is bonded to the first insulator 40 or not, the first trace 70 is arranged at a surface (such as the upper surface 41) of the first insulator 40 and at least a portion of the second lower surface 722 of the first trace 70 is arranged corresponding to the blind via 44 of the first insulator 40. And in case that the printed circuit board has a first conductive pad 30, the first conductive pad 30 is arranged at the other surface (such as the lower surface 42) of the first insulator 40. When at least a portion of the opening 34 of the first conductive pad 30 is arranged corresponding to the lower surface 72 of the first trace 70, some electronic elements may be arranged in the printed circuit board as demanded. For example, the predetermined blind via area 46 is replaced by the blind via 44, the vent 49 and the gate 47 are arranged, the predetermined vent area 48 is replaced by the vent 49, a portion of the second lower surface 722 of the first trace 70 is exposed to the vent 49, a portion of the second lower surface 722 of the first trace 70 is not exposed to the bottom of the vent 49, the ratio of the width of the blind via 44 of first insulator 40 to the length of the blind via 44 of first insulator 40 may enable to be between 0.01 and 0.79, Both the second insulator 4B and the second conductive pad 3B is further arranged, the second insulator 4B, the second conductive pad 3B, and the second trace 7B are further arranged so that the printed circuit board enable to become a multi-layer circuit board, the first trace 70 includes the second side 732 so that the second lower surface 722 of the first trace 70 is concavely or convexly arranged at the lower surface 72, at least a portion of the side edge 23 of the member 20 and the lower surface 22 are bonded to the first insulator 40, the member 20 is electrically connected with the printed circuit boards 50, 51, 52 through the conductive means such as a conductive wire, conductive bump, solder ball, tin material, or other suitable conductors, the member 20 and the encapsulant 60 are arranged at the same surface of the printed circuit boards 50, 51, 52, the solder mask 80 may be (or not) arranged at any one surface of the first insulator 40 as demanded, the protective layer 90 is bonded to the trace or the conductive pad which is exposed to the atmosphere, a conductive material is provided for bonding to and electrically connecting with the first trace 70, a conductive film (reference to the descriptions of FIG. 8B-2) may be arranged at the side wall of the blind via 44, the second lower surface 722 of the first trace 70, and/or the conductive pad 30 for being good to bond to other suitable conductors, the carrier sheet is arranged at any one surface of the printed circuit boards 51, 52 described as in FIGS. 12A to 14C, or any one kind of the printed circuit board as above mentioned may be connected with the member 20 and the encapsulant 60 by the traces and the conductive pads shown as in FIGS. 12A to 14C. They may make the printed circuit board be used much broader.

The following descriptions in accordance with the present invention are described the drilling process for a predetermined blind via area of first insulator of a printed circuit board being become a blind via of first insulator of said printed circuit board basically, wherein the step(s) of drilling the predetermined via of first insulator of printed circuit board can be provided either after the member, conductive means, and encapsulant are all arranged to the printed circuit board (refer to FIG. 12A to FIG. 12C and FIG. 14A to FIG. 14C) or before the member, conductive means, and encapsulant are all arranged to the printed circuit board (refer to FIG. 13A to FIG. 13D), The details are as following: Please, refer to FIG. 12A to 12C showing the drilling process for a predetermined blind via area 46 of first insulator 40 of a printed circuit board 51 being become a blind via 44 of first insulator of said printed circuit board 51, wherein the step of drilling the predetermined via area 46 of first insulator 40 of printed circuit board 51 is provided after the member 20, conductive means 10, and encapsulant 60 are all arranged to the printed circuit board 51, the steps are as followed: Step (1). Shown in FIG. 12A, providing a printed circuit board 51, the characteristics and the numbers of the printed circuit board 51 are almost the same as them of the printed circuit board 51 in FIG. 7B-1 to 7B-3, there are two differences described as follows: The printed circuit board 51 in FIG. 12A includes solder masks 80 which are arranged at both the upper surface 41 and the lower surface 42 of first insulator 40 respectively, and The predetermined blind via area 46 of first insulator 40 of printed circuit board 51 is instead of the blind via 44 of printed circuit board shown in FIG. 7B-1 to 7B-3; Step (2). shown in FIG. 12B, providing a member 20, conductive means 10 and encapsulant 60 which are all arranged at the same surface of printed circuit board 51 (i.e. the upper surface 41 of first insulator 40), wherein said member 20 is employed as a chip, said conductive means 10 are employed as conductive wires which are electrically connected said member 20 to said first traces 70 of printed circuit board 51 respectively, and said encapsulant 60 sealed said member 20, said conductive means 10 and said printed circuit board 51, as this result, a semiconductor package 100 is formed; Step (3). shown in FIG. 12C, providing a process of drilling (not shown) to remove the obstructers in the predetermined blind via area 46 so that the predetermined blind via area 46 becomes a real blind via (i.e. a through hole) 44 of first insulator 40, in this manner, it allows the second lower surface 722 of first trace 70 to be exposed to the blind via 44 of first insulator 40 for external connection; and Step (4). Still referring to FIG. 12C, providing a first conductive material 95 to fill into the blind via 44 of first insulator 40, wherein a portion of said first conductive material 95 received in said blind via 44 associated with the opening of said first conductive pad 30 and coupled with the second lower surface 722 of first trace 70 in order to electrically connect said first trace 70, wherein said first conductive material is exposed to the atmosphere, Moreover, due to said printed circuit board 51 further having a first conductive pad 30, then an another portion of said first conductive material 95 enables to be coupled with the upper surface 31 associated with the side wall of the opening 34 of first conductive pad 30, in this manner, it also allows said first trace 70 to be electrically connected to said first conductive pad 30 through said first conductive material 95, In addition, said first conductive material 95 is bonded to and electrically connected to a printed circuit board 52 which is considered to be employed as either any mentioned-above printed circuit board in accordance with the present invention or a conventional printed circuit board; Furthermore, the first conductive pad 30 of printed circuit board 51 is optional.

Please, refer to FIG. 13A to 13D showing the drilling process for a predetermined blind via area 46 of first insulator 40 of a printed circuit board 51 being become a blind via 44 of first insulator 40 of said printed circuit board 51, wherein the step of drilling the predetermined via area 46 of first insulator 40 of printed circuit board 51 is provided before the member 20, conductive means 10, and encapsulant 60 are all arranged to the printed circuit board 51, the steps are as followed: Step (1). Shown in FIG. 13A, providing a printed circuit board 51, the characteristics and the numbers of the printed circuit board 51 are almost the same as them of the printed circuit board 52 in FIG. 6A-1 to 6C-2, there are three differences described as follows: The predetermined blind via area 46 of first insulator 40 of printed circuit board 51 is instead of the blind via 44 of printed circuit board 52 shown in FIG. 6A-1 to 6C-2; The first conductive pad 30 of printed circuit board 51 which is instead of the first conductive pad 30 of printed circuit board 52 which is comprised of two metals; and There is a solder mask 80 bonded onto the upper surface 31 of first conductive pad 30; Step (2). shown in FIG. 13B, providing a process of drilling (not shown) to remove the obstructers in the predetermined blind via area 46 so that the predetermined blind via area 46 becomes a real blind via (i.e. a through hole) 44 of first insulator 40, in this manner, it allows the second lower surface 722 of first trace 70 to be exposed to the blind via 44 of first insulator 40 for external connection; Step (3). shown in FIG. 13C, providing a member 20, conductive means 10 and encapsulant 60 which are all arranged at the same surface of printed circuit board 51 (i.e. the lower surface 42 of first insulator 40), wherein said member 20 is employed as a flip chip, said conductive means 10 are employed as conductive bumps which are electrically connected said member 20 to said first conductive pads 30 of printed circuit board 51 respectively, and said encapsulant 60 sealed said member 20, said conductive means 10 and said printed circuit board 51, as this result, a semiconductor package 100 is formed; and Step (4). Shown in FIG. 13D, providing a first conductive material 95 to fill into the blind via 44 of first insulator 40, wherein a portion of said first conductive material 95 received in said blind via 44 associated with the opening of said first conductive pad 30 and coupled with the second lower surface 722 of first trace 70 in order to electrically connect said first trace 70, Moreover, an another portion of said first conductive material 95 coupled with the upper surface 31 associated with the side wall of the opening 34 of first conductive pad 30, wherein at least a portion of said first conductive material 95 is exposed to the atmosphere, wherein the distance between the top of the first conductive material 95 and the upper surface 31 of first conductive pad 30 is larger than 40 μm in this manner, Not only the first trace 70 but said first conductive pad 30 is electrically connected to aid first conductive material 95.

please, refer to FIG. 14A to 14C showing the drilling process for a predetermined blind via area 46 of first insulator 40 of a printed circuit board 51 being become a blind via 44 of first insulator 40 of said printed circuit board 51 are as followed: Step (1). Shown in FIG. 14A, providing two members 20 which are employed as chips; Step (2) still refer to FIG. 14A, providing two printed circuit boards 51,52 The structures of the printed circuit boards 51,52 are the same as the structure of the printed circuit board 50 shown in FIG. 1-2A, wherein each surface of printed circuit boards 51,52 (i.e. the lower surface 42 of first insulator 40) is coupled with a carrier sheet 88,85. The carrier sheet 85 may be made of metal such as a copper foil etc. or an insulator such as adhesive tape etc. Moreover, a film 86 which is made of either metal or insulator may be further arranged between the carrier sheet 85 and the surface of printed circuit board 52 so that the bond ability between the carrier sheet 85 and the printed circuit board 52 may be more secure; The carrier sheet 88 is made of metal and is unitary to the first conductive pad 30, said carrier sheet 88 coupled with the lower surface 42 of first insulator 40 of printed circuit board 51, wherein in case that both the carrier 88 and the first conductive pad 30 are unitary, then the peeling-off problem may be prevented; By means of the carrier sheets 51,52, the rigidity of printed circuit boards 51,52 enable to be enhanced before the encapsulant 60 is settled, in this manner, the risk of damage of printed circuit board due to insufficient rigidity may be prevented, and then each member 20 coupled with each surface (i.e. the upper surface 41 of first insulator 40) of said printed circuit boards 51,52 respectively; Step (3) still refer to FIG. 14A, providing conductive means 10 and encapsulants 60 which are arranged and settled on the same surfaces of printed circuit boards 51,52 with members 20 respectively, said conductive means 10 are employed as conductive wires which are electrically connected each member 20 to said first traces 70 of each printed circuit board 51,52 respectively, and said encapsulant 60 sealed said member 20, said conductive means 10 and said printed circuit boards 51,52 respectively; Step (4) shown in FIG. 14B, At first, providing a peeling-off process (not shown; such as an etching process or other suitable process) to remove the carrier sheets 88,85 from the printed circuit boards 51,52 respectively, so that each upper surface 31 of first conductive pad 30 is exposed to the atmosphere; Secondly, providing a process of drilling (not shown) to remove the obstructers in the predetermined blind via area 46 associated with the opening 34 of first conductive pad 30 so that the predetermined blind via area 46 becomes a real blind via (i.e. a through hole) 44 of first insulator 40, in this manner, it allows the second lower surface 722 of first trace 70 to be exposed to the blind via 44 of first insulator 40 for external connection; and Step (4). Shown in FIG. 14C, providing a conductive material to fill into the blind via 44 of first insulator 40, wherein said conductive material is comprised of a group of metals such as solder ball, solder paste etc. and/or a group of conductive layer such as a nickel, tin, gold, palladium, copper or the like, and said group of metal is employed as a first conductive material 95, said group of conductive layer is employed as a second conductive material 9B; as shown in FIG. 14C, at first, a second conductive material 9B is filled into and received in the real via 44 of first insulator 40 of printed circuit board 52 in order to be coupled with the second lower surface 722 of first trace 70 of printed circuit board 52, then a first conductive material 95 also filled into the blind via 44 of printed circuit board 52, wherein a portion of first conductive material 95 received in the blind via 44 associated with the opening 34 of first conductive pad 30 and coupled with the second conductive material 9B, meanwhile an another portion of first conductive material 95 coupled with the upper surface 31 of first conductive pad 30, so that the first trace 70 of printed circuit board 52 can be electrically connected to the first conductive pad 30 through the conductive material which is comprised of both the first conductive material 95 and the second conductive material 9B, wherein said first conductive material 95 is exposed to the atmosphere; By means of the second conductive material 9B, the distance between the second lower surface 722 of first trace 70 and the first conductive pad 30 is shortened, then it is easier for the first conductive material 95 to be electrically connected to the first conductive pad 30; The conductive material coupled with the printed circuit board 51 is comprised of the first conductive material 95 exclusively; Moreover, in case that the first conductive material 95 of printed circuit board 52 is omitted, then the conductive material of printed circuit board 52 is comprised of the second conductive material 9B exclusively. In addition, the first conductive pads 30 coupled with the lower surface 42 of insulator of printed circuit boards 51, 52 are optional; either the carrier sheet 85 or the carrier sheet 88 enables to be stacked a further carrier sheet(s), Moreover, in case that each carrier sheet (85,88) further having an opening 84 which is corresponding to each blind via 44, then the carrier sheet enables to be always coupled with the printed circuit board (52,51), so that said carrier sheet is/are not removed from said printed circuit board (52,51) for enhancing the rigidity of said printed circuit board (52,51) as demanded; In addition, the process for the predetermined blind via area 46 of first insulator 40 being become a via 44 (FIG. 14A-14C), wherein the side edge (numbered 23 in FIG. 3) of member 20 may also be coupled with said first insulator 40 and electrically connected to the printed circuit board (51,52) as demanded, and then being sealed by said encapsulant 60.

The printed circuit board structure using the process of electrically connecting the trace of the printed circuit board structure with the conductive pad after combining the printed circuit board structure with the encapsulant in FIGS. 12A to 14C may be replaced by any one of the printed circuit board structure in FIGS. 1-1 to 14C as demanded. The member 20 and the encapsulant 60 may be arranged at any one surface of the printed circuit board and the carrier sheet 85, 88 is arranged at the other surface of the printed circuit board as demanded.

The foregoing descriptions are merely the exemplified embodiments of the present invention, where the scope of the claim of the present invention is not intended to be limited by the embodiments. Any equivalent embodiments or modifications without departing from the spirit and scope of the present invention are therefore intended to be embraced.

The disclosed structure of the invention has not appeared in the prior art and features efficacy better than the prior structure which is construed to be a novel and creative invention, thereby filing the present application herein subject to the patent law.

What is claimed is:

1. A printed circuit board for being coupled with a member which is selectively served as one of: a chip, a flip chip or a semiconductor package and is electrically connected to said printed circuit board, comprised of:
a first trace including a first side edge, an upper surface, and a lower surface, a portion of the lower surface of first trace is employed as a second lower surface of first trace, and the upper surface of said first trace is provided for being electrically connected to an external connection; and
a first insulator having an upper surface, a lower surface, and a predetermined blind via area which is comprised of an obstructer, said obstructer is received in said predetermined blind via area and is formed by a portion of the first insulator, said first trace is coupled with the upper surface of said first insulator, wherein at least a portion of the lower surface of said first trace is coupled with said first insulator, wherein said second lower surface of first trace is corresponding to said predetermined blind area and is coupled with said obstructer which is received in said predetermined via area, and wherein said obstructer received in said predetermined blind via area of first insulator is prepared for being removed from said predetermined blind via area of first insulator, and wherein the second lower surface of first trace is used for being electrically connected to a conductive material, wherein at least a portion of said conductive material being exposed to the atmosphere.

2. The printed circuit board as claimed in claim 1, wherein the first insulator further includes at least a predetermined vent area, and said predetermined vent area is adjacent to said predetermined blind via area.

3. The printed circuit board as claimed in claim 1, wherein at least a portion of the first side edge of the first trace coupled with the first insulator so that the upper surface of the first trace is flatly, concavely, or convexly arranged at the upper surface of the first insulator.

4. The printed circuit board as claimed in claim 1, further comprising a first conductive pad, the first conductive pad includes a side edge, an upper surface, and a lower surface, the upper surface of the first conductive pad is provided for being electrically connected to the external connection, the first conductive pad is coupled with the lower surface of the first insulator, wherein at least a portion of the lower surface of said first conductive pad is coupled with said first insulator, and wherein at least a portion of said first conductive pad is corresponding to said lower surface of first trace.

5. The printed circuit board as claimed in claim 4, wherein said first conductive pad further comprising at least an opening.

6. The printed circuit board as claimed in claim 4, wherein at least a portion of the side edge of the first conductive pad coupled with the first insulator so that the upper surface of the first conductive pad is flatly, concavely, or convexly arranged at the lower surface of the first insulator.

7. The printed circuit board as claimed in claim 4, further comprising a carrier sheet, said carrier sheet is bonded to said printed circuit board associated with said first conductive pad, wherein said carrier sheet is unitary to said first conductive pad.

8. The printed circuit board as claimed in claim 1, further comprising a carrier sheet, said carrier sheet is bonded to said printed circuit board.

9. The printed circuit board as claimed in claim 8, wherein said carrier sheet having at least an opening.

10. The printed circuit board as claimed in claim 1, further comprising a member which is comprised of an upper surface, a lower surface, and a side edge, the upper surface of said member having a plurality of conductive pads for external connection, wherein both the lower surface of said member and at least a portion of the side edge of said member are coupled with the first insulator so that the upper surface of said member is flatly, concavely, or convexly arranged at the upper surface of the first insulator, wherein said member is employed as a chip.

11. The printed circuit board as claimed in claim 1, wherein the first trace further includes a second side edge, the second side edge is arranged between the lower surface of the first trace and the second lower surface of the first trace so that the second lower surface of the first trace is concavely or convexly arranged at the lower surface of the first trace.

12. The printed circuit board as claimed in claim 1, further comprising a second insulator and a second conductive pad, the upper surface of the first trace further includes a second upper surface, the second insulator includes an upper surface, a lower surface, and a blind via which is penetrated through said second insulator, the lower surface of the second insulator is bonded to the upper surface of the first insulator and covered at least a portion of the first trace, the blind via of the second insulator is arranged corresponding to the second upper surface of the first trace so that the second upper surface of the first trace is exposed to the blind via of the second insulator; the second conductive pad includes a side edge, an opening, an upper surface, and a lower surface, the upper surface of second conductive pad is provided for external connection, the second conductive pad is arranged at the upper surface of the second insulator, and the opening of the second conductive pad is arranged corresponding to the second upper surface of the first trace, so that the second upper surface of first trace enables to be exposed to the opening of second conductive pad.

13. The printed circuit board as claimed in claim 12, further comprising a second trace, the second trace is arranged at the upper surface of the second conductive pad, wherein a portion of the second trace is received in both the blind via of the second insulator and the opening of the second conductive pad in order to electrically connect to the second upper surface of the first trace.

14. The printed circuit board as claimed in claim 1, wherein said first insulator further includes a thickness, and the predetermined blind via area of said first insulator having a width, in this manner, the ratio of the thickness of the first insulator to the width of the predetermined blind via area of the first insulator is equal to or smaller than 0.5.

15. The printed circuit board as claimed in claim 4, wherein a portion of said predetermined blind via area of said first insulator protrudes the side edge of said first conductive pad.

16. The printed circuit board as claimed in claim 15, wherein said first conductive pad is comprised of one or a plurality of metals.

17. A printed circuit board for being coupled with a member which is selectively served as one of: a chip, a flip chip or a semiconductor package and is electrically connected to said printed circuit board, comprised of:
a first trace including a first side edge, an upper surface, and a lower surface, a portion of the lower surface of first trace is employed as a second lower surface of first trace, and the upper surface of said first trace is provided for being electrically connected to the external connection; and
a first insulator having an upper surface, a lower surface, and a blind via which is penetrated through said first insulator, said blind via of first insulator having both a width and a length, wherein said width of first insulator is shorter than said length of first insulator, said first trace is coupled with the upper surface of said first insulator, wherein at least a portion of the lower surface of said first trace is coupled with said first insulator, and wherein said second lower surface of first trace is corresponding to said blind via and is exposed to the atmosphere for being electrically connected to a conductive material, wherein at least a portion of said conductive material being exposed to the atmosphere.

18. The printed circuit board as claimed in claim 17, wherein at least a portion of the first side edge of the first trace coupled with the first insulator so that the upper surface of the first trace is flatly, concavely, or convexly arranged at the upper surface of the first insulator.

19. The printed circuit board as claimed in claim 17, further comprising a first conductive pad, the first conductive pad includes a side edge, an upper surface, a lower surface, and an opening, the upper surface of the first conductive pad is provided for being electrically connected to an external connection, the first conductive pad is coupled with the lower surface of the first insulator, wherein at least a portion of the lower surface of said first conductive pad is coupled with said first insulator, at least a portion of said opening of first conductive pad is corresponding to the lower surface of the first trace.

20. The printed circuit board as claimed in claim 19, wherein at least a portion of the side edge of the first conductive pad coupled with the first insulator so that the upper surface of the first conductive pad is flatly, concavely, or convexly arranged at the lower surface of the first insulator.

21. The printed circuit board as claimed in claim 19, further comprising a carrier sheet, said carrier sheet is bonded to said printed circuit board associated with said first conductive pad, wherein said carrier sheet is unitary to said first conductive pad.

22. The printed circuit board as claimed in claim 17, further comprising a carrier sheet, said carrier sheet is bonded to said printed circuit board.

23. The printed circuit board as claimed in claim 22, wherein said carrier sheet having at least an opening.

24. The printed circuit board as claimed in claim 17, wherein the first trace further includes a second side edge, the second side edge is arranged between the lower surface of the first trace and the second lower surface of the first trace so that the second lower surface of the first trace is concavely or convexly arranged at the lower surface of the first trace.

25. The printed circuit board as claimed in claim 17, further comprising a second insulator and a second conductive pad, the upper surface of the first trace further includes a second upper surface, the second insulator includes an upper surface, a lower surface, and a blind via which is penetrated through said second insulator, the lower surface of the second insulator is bonded to the upper surface of the first insulator and covered at least a portion of the first trace, the blind via of the second insulator is arranged corresponding to the second upper surface of the first trace so that the second upper surface of the first trace is exposed to the blind via of the second insulator; the second conductive pad includes a side edge, an opening, an upper surface, and a lower surface, the upper surface of second conductive pad is provided for external connection, the second conductive pad is arranged at the upper surface of the second insulator, and the opening of the second conductive pad is arranged corresponding to the second upper surface of the first trace, so that the second upper surface of first trace enables to be exposed to the opening of second conductive pad.

26. The printed circuit board as claimed in claim 25, further comprising a second trace, the second trace is arranged at the upper surface of the second conductive pad, wherein a portion of the second trace is received in both the blind via of the second insulator and the opening of the second conductive pad in order to electrically connect to the second upper surface of the first trace.

27. The printed circuit board as claimed in claim 17, further comprising a member which is comprised of an upper surface, a lower surface, and a side edge, the upper surface of said member having a plurality of conductive pads for external connection, wherein both the lower surface of said member and at least a portion of the side edge of said member are coupled with the first insulator so that the upper surface of said member is flatly, concavely, or convexly arranged at the upper surface of the first insulator, wherein said member is employed as a chip.

28. The printed circuit board as claimed in claim 17, wherein said first insulator further includes a thickness, in this manner, the ratio of the thickness of the first insulator to the length of the blind via of the first insulator is equal to or smaller than 0.5.

29. The printed circuit board as claimed in claim 17, wherein said blind via further having at least a vent which is adjacent to said blind via and at least a gate which is between said blind via and said vent.

30. The printed circuit board as claimed in claim 19, wherein a portion of said blind via of said first insulator protrudes the side edge of said first conductive pad.

31. The printed circuit board as claimed in claim 30, wherein said first conductive pad is comprised of one or a plurality of metals.

32. The printed circuit board as claimed in claim 17, wherein the ratio of the width of the blind via of first insulator to the length of the blind via of first insulator is between 0.01 and 0.79.

33. A drilling process for a predetermined blind via area of first insulator of a printed circuit board being become a blind via of first insulator of said printed circuit board, comprised of:
step (1). providing a member which is selectively served as one of: a chip, a flip chip or a semiconductor package;
step (2). providing a printed circuit board which is comprised of:
a first trace including a first side edge, an upper surface, and a lower surface, a portion of the lower surface of first trace is employed as a second lower surface of first trace, and the upper surface of said first trace is provided for external connection; and
a first insulator having an upper surface, a lower surface, and a predetermined blind via area which is comprised of an obstructer, said obstructer is received in said predetermined blind via area and is formed by a portion of the first insulator, said first trace is coupled with the upper surface of said first insulator, wherein at least a portion of the lower surface of said first trace is coupled with said first insulator, wherein said second lower surface of first trace is corresponding to said predetermined blind area and is coupled with said obstructer which is received in said predetermined via area, and wherein at least a portion of the member coupled with said printed circuit board, and said member electrically connected to said printed circuit board;
step (3). providing an encapsulant for sealing at least a portion of said member and said printed circuit board; and
step (4). Providing a process of drilling to remove the obstructer received in the predetermined blind via area so that the predetermined blind via area being become a blind via which is penetrated through said first insulator, in this manner, said second lower surface of first trace is corresponding to said blind via and is exposed to the atmosphere for being electrically connected to a conductive material, wherein at least a portion of said conductive material being exposed to the atmosphere.

34. The drilling process for a predetermined blind via area of first insulator of a printed circuit board being become a blind via of first insulator of said printed circuit board as claimed in claim 33, wherein after the step (4) accomplished, further comprised of a step (5), said step (5) is comprised of providing a conductive material to fill into the blind via of first insulator, wherein at least a portion of said conductive material received in said blind via and coupled with the second lower surface of first trace, in this manner, said first trace of printed circuit board electrically connected to said conductive material.

35. The drilling process for a predetermined blind via area of first insulator of a printed circuit board being become a blind via of first insulator of said printed circuit board as claimed in claim 33, wherein said predetermined blind via area of said first insulator further includes at least a predetermined vent area which is adjacent to said predetermined blind via area, and wherein said predetermined vent area becomes a vent after the step (4) accomplished.

36. The drilling process for a predetermined blind via area of first insulator of a printed circuit board being become a blind via of first insulator of said printed circuit board as claimed in claim 33, wherein said printed circuit board further comprising a first conductive pad, the first conductive pad includes a side edge, an upper surface, and a lower surface, the upper surface of the first conductive pad is provided for being electrically connected to an external connection, the first conductive pad is coupled with the lower surface of the first insulator, wherein at least a portion of the lower surface of said first conductive pad is coupled with said first insulator.

37. The drilling process for a predetermined blind via area of first insulator of a printed circuit board being become a blind via of first insulator of said printed circuit board as claimed in claim 36, wherein said first conductive pad further comprising an opening, and wherein at least a portion of said opening of first conductive pad is corresponding to the lower surface of the first trace.

38. The drilling process for a predetermined blind via area of first insulator of a printed circuit board being become a blind via of first insulator of said printed circuit board as claimed in claim 33, further comprising a carrier sheet, said carrier sheet is bonded to said printed circuit board.

39. The drilling process for a predetermined blind via area of first insulator of a printed circuit board being become a blind via of first insulator of said printed circuit board as claimed in claim 38, wherein said carrier sheet further includes at least an opening.

40. The drilling process for a predetermined blind via area of first insulator of a printed circuit board being become a blind via of first insulator of said printed circuit board as claimed in claim 38, wherein said carrier sheet is removed from said printed circuit board.

41. The drilling process for a predetermined blind via area of first insulator of a printed circuit board being become a blind via of first insulator of said printed circuit board as claimed in claim 33, wherein said member is comprised of an upper surface, a lower surface, and a side edge, the upper surface of said member having a plurality of conductive pads for external connection, wherein both the lower surface of said member and at least a portion of the side edge of said member are coupled with the first insulator so that the upper surface of said member is flatly, concavely, or convexly arranged at the upper surface of the first insulator, wherein said member is employed as a chip.

42. The drilling process for a predetermined blind via area of first insulator of a printed circuit board being become a blind via of first insulator of said printed circuit board as claimed in claim 36, wherein after the step (4) accomplished, further comprised of a step (5), said step (5) is comprised of providing a conductive material to fill into the blind via of first insulator, wherein a portion of said conductive material received in said blind via, and wherein said conductive material is coupled with both the second lower surface of first trace and the first conductive pad, in this manner, said first trace of printed circuit board electrically connected to said first conductive pad.

43. The drilling process for a predetermined blind via area of first insulator of a printed circuit board being become a blind via of first insulator of said printed circuit board as claimed in claim 33, wherein after the step (4) accomplished, the blind via of first insulator having both a width and a length, said width of blind via is shorter than said length of blind via, wherein the ratio of the width of the blind via of first insulator to the length of the blind via of first insulator is between 0.01 and 0.79.
